(19) United States
(12) Patent Application Publication
(10) Pub. No.: US 2025/0268084 A1
(43) Pub. Date: Aug. 21, 2025

(54) DISPLAY DEVICE

(71) Applicant: Samsung Display Co., LTD., Yongin-si (KR)

(72) Inventors: Gi Na YOO, Yongin-si (KR); Seung Han KIM, Yongin-si (KR); Hyo Min KIM, Yongin-si (KR)

(21) Appl. No.: 18/927,017

(22) Filed: Oct. 25, 2024

(30) Foreign Application Priority Data
Feb. 19, 2024 (KR) 10-2024-0023566

(51) Int. Cl. H10K 59/80; H01L 27/15; H10K 59/35; H10K 59/38; H10K 59/40; H10K 102/00

(52) U.S. Cl. CPC H10K 59/8792; H10H 29/142; H10K 59/38; H10K 59/873; H10K 59/351; H10K 59/40; H10K 2102/351

(57) ABSTRACT

A display device includes a display area in which a plurality of first pixels and second pixels including a plurality of pixel electrodes spaced apart from each other are disposed, a first light blocking layer disposed in the display area and including a plurality of holes disposed to overlap the pixel electrodes, a plurality of color filters disposed on the first light blocking layer to correspond to the holes, and a second light blocking layer disposed on the color filter and disposed to correspond to the pixel electrodes of the second pixels, the first light blocking layer including a plurality of divided portions disposed around the holes of the second pixel and penetrating the first light blocking layer, and the color filters disposed in the second pixel and disposed to cover the hole of the first light blocking layer, where the divided portions are disposed to correspond to the holes.

This application claims priority to Korean Patent Application No. 10-2024-0023566, filed on Feb. 19, 2024, and all the benefits accruing therefrom under 35 U.S.C. § 119, the content of which in its entirety is herein incorporated by reference.

### BACKGROUND

### 1. Field

The present disclosure relates to a display device.

### 2. Description of the Related Art

With the advance of an information-oriented society, more and more demands are being placed on display devices to display images in various ways. For example, display devices are employed in various electronic devices such as smartphones, digital cameras, laptop computers, navigation devices, and smart televisions and may be a flat panel display device such as a liquid crystal display device, a field emission display device and an organic light emitting display device. Among the flat panel display devices, in the light emitting display device, since each of the pixels of a display panel include a light emitting element capable of emitting light by itself, an image can be displayed without a backlight unit providing light to the display panel.

### SUMMARY

Aspects of the invention provide a display device including a plurality of light blocking layers disposed in different layers.

Aspects of the invention provide a display device that is capable of providing a privacy protection mode by including the light blocking layer disposed on some pixels.

However, aspects of the invention are not restricted to those set forth herein. The above and other aspects of the invention will become more apparent to one of ordinary skill in the art to which the invention pertains by referencing the detailed description of the invention given below.

According to an aspect of the invention, there is provided a display device including, a display area in which a plurality of first pixels and second pixels including a plurality of pixel electrodes spaced apart from each other are disposed, a first light blocking layer disposed in the display area and including a plurality of holes disposed to overlap the plurality of pixel electrodes, a plurality of color filters disposed on the first light blocking layer and respectively disposed to correspond to the plurality of holes, and a second light blocking layer disposed on the color filter and disposed to correspond to the pixel electrode of the plurality of second pixels, wherein the first light blocking layer includes a plurality of divided portions disposed around the holes of the second pixel and penetrating the first light blocking layer, and the plurality of color filters disposed in the second pixel are disposed to cover the hole of the first light blocking layer and the divided portion disposed to correspond to the hole.

In an embodiment, the first light blocking layer includes a first hole overlapping a first pixel electrode of the first pixel, a second hole overlapping a second pixel electrode of the first pixel, a third hole overlapping a first pixel electrode of the second pixel, and a fourth hole overlapping a second pixel electrode of the second pixel, wherein a diameter of the first hole is larger than a diameter of the third hole.

In an embodiment, a distance between the first hole and the second hole in the first pixel is smaller than a distance between the third hole and the fourth hole in the second pixel.

In an embodiment, the plurality of divided portions include a first divided portion surrounding the third hole, and a second divided portion surrounding the fourth hole, wherein a diameter of a region surrounded by the first divided portion is larger than a diameter of a region surrounded by the second divided portion.

In an embodiment, the second divided portion includes a first sub-divided portion surrounding the fourth hole, and a second sub-divided portion surrounding the first sub-divided portion.

In an embodiment, the plurality of divided portions are spaced apart from an outer side of the plurality of holes located in the second pixel, and have a curved shape along the outer side.

In an embodiment, the plurality of divided portions are disposed between the plurality of holes located in the second pixel.

In an embodiment, the pixel includes a first pixel electrode, and a second pixel electrode having a diameter smaller than that of the first pixel electrode, and wherein the second light blocking layer includes, a first light blocking pattern surrounding an outer side of the first pixel electrode and forming a first transmission portion overlapping the first pixel electrode, and a second light blocking pattern surrounding an outer side of the second pixel electrode and forming a second transmission portion overlapping the second pixel electrode.

In an embodiment, a diameter of the first transmission portion is smaller than a diameter of the second transmission portion.

In an embodiment, a separation distance between the outer side of the first pixel electrode and an inner side of the first light blocking pattern is different from a separation distance between the outer side of the second pixel electrode and an inner side of the second light blocking pattern.

According to an aspect of the invention, there is provided a display device including, a substrate on which a first pixel and a second pixel including a plurality of pixel electrodes are disposed, an encapsulation layer disposed on the plurality of pixel electrodes, a first light blocking layer disposed on the encapsulation layer and including a plurality of holes each of which being disposed to correspond to the pixel electrode, a plurality of color filters disposed on the first light blocking layer and respectively disposed to correspond to the plurality of holes, a passivation layer disposed on the color filters and the first light blocking layer, a second light blocking layer disposed on the passivation layer in the second pixel and including a plurality of light blocking patterns forming a plurality of transmission portions each overlapping the pixel electrode of the second pixel, and an overcoat layer disposed on the second light blocking layer, wherein the pixel electrode includes a first pixel electrode and a second pixel electrode having a diameter smaller than that of the first pixel electrode, which are disposed in each of the first pixel and the second pixel, the first light blocking layer is disposed around the plurality of holes disposed in the second pixel, and includes a plurality of divided portions penetrating the first light blocking layer, and among the color filters, the color filters disposed in the second pixel are disposed to cover the divided portion.

In an embodiment, the passivation layer includes a first passivation layer disposed on the first light blocking layer and the color filter, and a second passivation layer disposed on the first passivation layer.

In an embodiment, the first passivation layer is disposed to cover the color filters and the first light blocking layer in the first pixel, and is patterned to partially expose the plurality of color filters in the second pixel.

In an embodiment, the first passivation layer has a refractive index that is lower than that of the second passivation layer.

In an embodiment, the first passivation layer is in contact with the second passivation layer that is disposed on the color filter disposed in the second pixel and forms an inclined side surface.

In an embodiment, the first light blocking layer includes, a first hole overlapping the first pixel electrode of the first pixel, a second hole overlapping the second pixel electrode of the first pixel, a third hole overlapping the first pixel electrode of the second pixel, and a fourth hole overlapping the second pixel electrode of the second pixel, wherein a diameter of the first hole is larger than a diameter of the third hole, and wherein a thickness of the color filter disposed on the first hole among the color filters is smaller than a thickness of the color filter disposed on the third hole.

In an embodiment, among the color filters, a thickness of the color filter disposed on the second hole is smaller than a thickness of the color filter disposed on the fourth hole.

In an embodiment, a difference in thickness between the color filter disposed on the first hole and the color filter disposed on the third hole is different from a difference in thickness between the color filter disposed on the second hole and the color filter disposed on the fourth hole.

In an embodiment, the plurality of color filters overlap each other on the first light blocking layer.

In an embodiment, the color filter disposed on the second hole is disposed on the color filter disposed on the first hole on the first light blocking layer.

The display device, according to an embodiment, may include the plurality of light blocking layers, wherein the plurality of light blocking layers may have a shape that corresponds to and that surrounds a pixel electrode. The display device may include divided portions formed in a light blocking layer to reduce thickness deviation of a color filter according to the width of the light blocking layer that is disposed in different pixels, and thus may reduce a transmittance difference.

However, effects according to the embodiments of the invention are not limited to those exemplified above and various other effects are incorporated herein.

### BRIEF DESCRIPTION OF THE DRAWINGS

The above and other aspects and features of the invention will become more apparent by describing in detail embodiments thereof with reference to the attached drawings, in which:

FIG. 1 is a schematic perspective view of an electronic device, according to an embodiment;

FIG. 2 is a perspective view illustrating a display device included in an electronic device, according to an embodiment;

FIG. 3 is a cross-sectional view of the display device of FIG. 2 viewed from the side, according to an embodiment;

FIG. 4 is a plan view of the disposition of pixel electrodes in the display area of the display device, according to an embodiment;

FIG. 5 is a plan view illustrating the disposition of a pixel electrode and a first light blocking layer in the display area of the display device, according to an embodiment;

FIG. 6 is a plan view illustrating the disposition of a pixel electrode and a second light blocking layer in the display area of the display device, according to an embodiment;

FIG. 7 is a schematic diagram illustrating light emitting pixels according to an emission mode of the display device, according to an embodiment;

FIG. 8 is a cross-sectional view taken along line X1-X1′ of the display device of FIG. 5 and FIG. 6, according to an embodiment;

FIG. 9 is a cross-sectional view taken along line X2-X2′ of the display device of FIG. 5 and FIG. 6, according to an embodiment;

FIG. 10 is a cross-sectional view taken along lines X3-X3′ and X4-X4′ of the display device of FIG. 5 and FIG. 6, according to an embodiment;

FIG. 11 is a diagram illustrating the relative disposition of a pixel electrode and a first light blocking layer disposed in one pixel of the display device, according to an embodiment;

FIG. 12 is a diagram showing a cross section of a second pixel of a display device, according to an embodiment;

FIG. 13 is a diagram showing a cross section of a first pixel and a second pixel of a display device, according to an embodiment;

FIG. 14 is a plan view illustrating the disposition of a pixel electrode and a first light blocking layer in a display area of a display device, according to an embodiment;

FIG. 15 is a plan view illustrating the disposition of a pixel electrode and a first light blocking layer in a display area of a display device, according to an embodiment;

FIG. 16 is a plan view illustrating the disposition of a pixel electrode and a first light blocking layer in a display area of a display device, according to an embodiment;

FIG. 17 is a cross-sectional view of a display device, according to an embodiment;

FIG. 18 is a cross-sectional view of a display device, according to an embodiment;

FIG. 19 is a cross-sectional view of a display device, according to an embodiment; and

FIG. 20 is a cross-sectional view of a display device, according to an embodiment.

### DETAILED DESCRIPTION

The invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions are exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

It will also be understood that when a layer is referred to as being “connected to” or “coupled to” another element, layer or substrate, it can be directly on the other element, layer or substrate, or intervening elements, layers or substrates may also be present. Likewise, those referred to as “Below”, “Left”, and “Right” include cases where they are directly adjacent to other elements or cases where another layer or other material is interposed. To this end, the term “connected” may refer to physical, electrical, and/or fluid connection, with or without intervening elements.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, ZZ, or the like. As used herein, the term “and/or” includes any and all combinations of one or more of the associated listed items.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments may be described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and, as such, are not intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the invention. Further, the blocks, units, parts, and/or modules of some embodiments may be physically combined into more complex blocks, units, parts, and/or modules without departing from the scope of the invention.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments will be described with reference to the accompanying drawings.

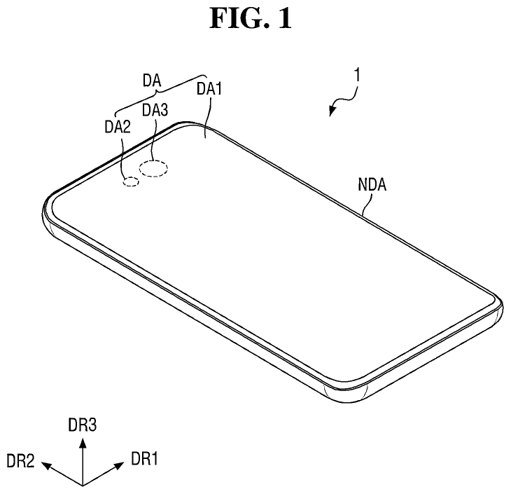

FIG. 1 is a schematic perspective view of an electronic device, according to an embodiment.

In an embodiment and referring to FIG. 1, an electronic device 1 displays a moving image or a still image. The electronic device 1 may refer to any electronic device providing a display screen. Examples of the electronic device 1 may include a television, a laptop computer, a monitor, a billboard, an Internet-of-Things device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder and the like, which provide a display screen.

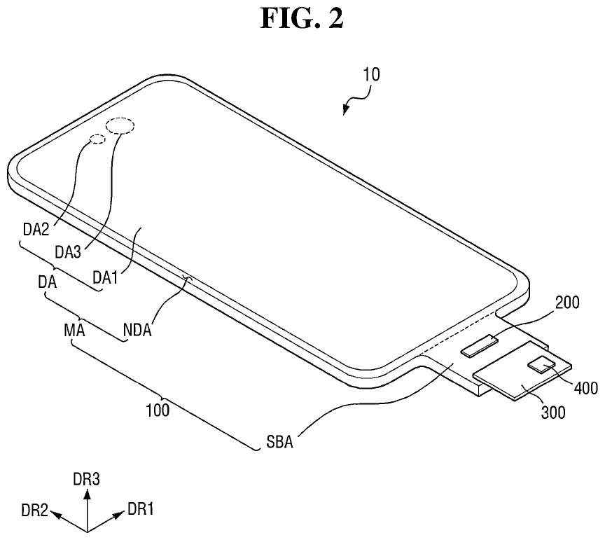

In an embodiment, the electronic device 1 may include a display device 10, as shown in FIG. 2, providing a display screen. Examples of the display device 10 may include an inorganic light emitting diode display device, an organic light emitting display device, a quantum dot light emitting display device, a plasma display device and a field emission display device. In the following description, a case where an organic light emitting diode display device is applied as a display device will be exemplified, but the invention is not limited thereto, and other display devices may be applied within the same scope of technical spirit.

In an embodiment, the shape of the electronic device 1 may be variously modified. For example, the electronic device 1 may have a shape such as a rectangular shape elongated in a horizontal direction, a rectangular shape elongated in a vertical direction, a square shape, a quadrilateral shape with rounded corners (vertices), other polygonal shapes and a circular shape. The shape of a display area DA of the electronic device 1 may also be similar to the overall shape of the electronic device 1. FIG. 1 illustrates the electronic device 1 having a rectangular shape elongated in a second direction DR2.

The electronic device 1 may include the display area DA and a non-display area NDA, where the display area DA is an area where a screen can be displayed, and the non-display area NDA is an area where a screen is not displayed. The display area DA may also be referred to as an active region, and the non-display area NDA may also be referred to as a non-active region. The display area DA may substantially occupy the center of the electronic device 1.

In an embodiment, the display area DA may include a first display area DAI, a second display area DA2, and a third display area DA3. The second display area DA2 and the third display area DA3 are areas in which components for adding various functions to the electronic device 1 are disposed, and the second display area DA2 and the third display area DA3 may correspond to a component area.

FIG. 2 is a perspective view illustrating a display device included in an electronic device, according to an embodiment.

In an embodiment and referring to FIG. 2, the electronic device 1 may include the display device 10, where the display device 10 may provide a screen displayed by the electronic device 1. The display device 10 may have a planar shape similar to the shape of the electronic device 1. For example, the display device 10 may have a shape similar to a rectangular shape having a short side in a first direction DR1 and a long side in the second direction DR2. The edge where the short side in the first direction DR1 and the long side in the second direction DR2 meet may be rounded to have a curvature, but is not limited thereto and may be formed at a right angle. The planar shape of the display device 10 is not limited to a quadrilateral shape, and may be formed in a shape similar to another polygonal shape, a circular shape, or elliptical shape.

In an embodiment, the display device 10 may include a display panel 100, a display driver 200, a circuit board 300, and a touch driver 400, where the display panel 100 may include a main region MA and a sub-region SBA.

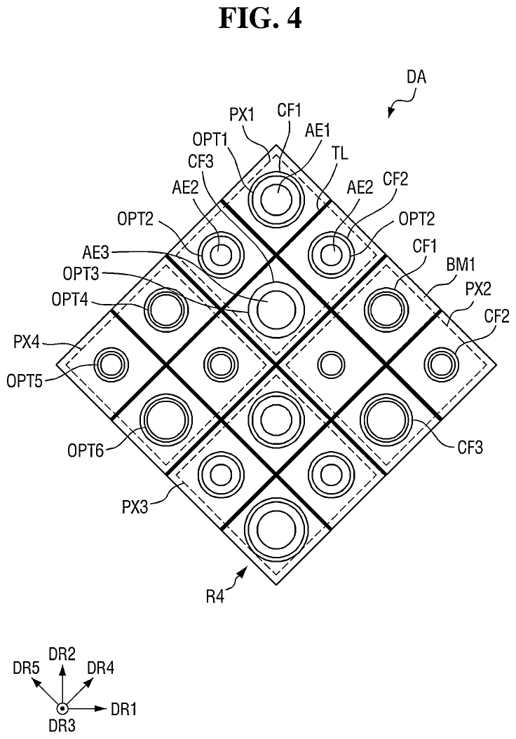

The main region MA may include the display area DA including pixels PX1, PX2, PX3, and PX4 (see FIG. 4) that display images, and the non-display area NDA disposed around the display area DA. The display area DA may be disposed in the center of the main region MA, and the non-display area NDA may surround the display area DA. The display area DA may include the first display area DA1, the second display area DA2, and the third display area DA3. The display area DA may emit light from a plurality of emission areas or a plurality of opening areas. In an embodiment, the display panel 100 may include a pixel circuit including switching elements, a pixel defining layer defining an emission area or an opening area, and a self-light emitting element.

For example, the self-light emitting element may include at least one of an organic light emitting diode (LED) including an organic light emitting layer, a quantum dot LED including a quantum dot light emitting layer, an inorganic LED including an inorganic semiconductor, or a micro LED, but is not limited thereto.

The non-display area NDA may be an area disposed outside of the display area DA and may be defined as an edge area of the main region MA of the display panel 100. The non-display area NDA may include a gate driver (not illustrated) that supplies gate signals to the gate lines, and fan-out lines (not illustrated) that connect the display driver 200 to the display area DA.

In an embodiment, the sub-region SBA may be a region extending from one side of the main region MA and may include a flexible material which can be bent, folded or rolled. For example, when the sub-region SBA is bent, the sub-region SBA may overlap the main region MA in a thickness direction (third direction DR3). The sub-region SBA may include the display driver 200 and a pad portion connected to the circuit board 300. In another embodiment, the sub-region SBA may be omitted, and the display driver 200 and the pad portion may be disposed in the non-display area NDA.

In an embodiment, the display driver 200 may output signals and voltages for driving the display panel 100, where the display driver 200 may supply data voltages to data lines. The display driver 200 may supply a power voltage to the power line and may supply a gate control signal to the gate driver. The display driver 200 may be formed as an integrated circuit (IC) and mounted on the display panel 100 by a chip on glass (COG) method, a chip on plastic (COP) method, or an ultrasonic bonding method. In an embodiment, the display driver 200 may be disposed in the sub-region SBA, and may overlap the main region MA in the thickness direction by bending of the sub-region SBA. In another embodiment, the display driver 200 may be mounted on the circuit board 300.

In an embodiment, the circuit board 300 may be attached to the pad portion of the display panel 100 by using an anisotropic conductive film (ACF). Lead lines of the circuit board 300 may be electrically connected to the pad portion of the display panel 100. The circuit board 300 may be a flexible printed circuit board, a printed circuit board, or a flexible film such as a chip on film.

In an embodiment, the touch driver 400 may be mounted on the circuit board 300. The touch driver 400 may be connected to a touch sensing unit of the display panel 100. The touch driver 400 may supply a touch driving signal to a plurality of touch electrodes of the touch sensing unit and may sense an amount of change in capacitance between the plurality of touch electrodes. For example, the touch driving signal may be a pulse signal having a predetermined frequency. The touch driver 400 may calculate whether an input is made and input coordinates based on an amount of change in capacitance between the plurality of touch electrodes. The touch driver 400 may be formed as an integrated circuit (IC).

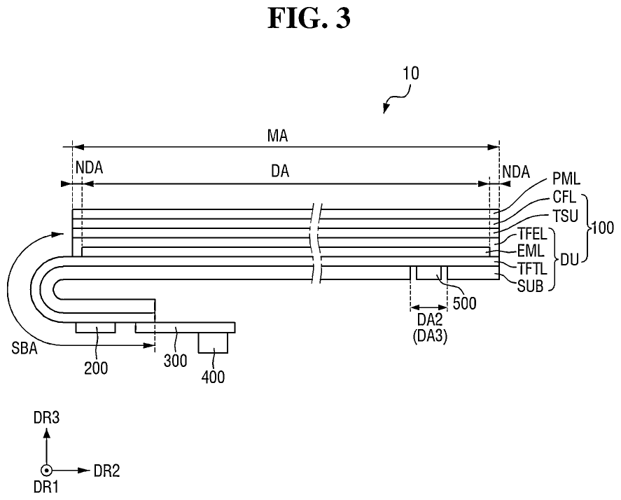

FIG. 3 is a cross-sectional view of the display device of FIG. 2 viewed from the side, according to an embodiment. FIG. 3 illustrates the sub-region SBA of the display panel 100 in the display device 10 of FIG. 2 in a folded state.

In an embodiment and referring to FIG. 3, the display panel 100 may include a display layer DU, a touch sensing layer TSU, a color filter layer CFL, and a light blocking member layer PML. The display layer DU may include a substrate SUB, a thin film transistor layer TFTL, a light emitting element layer EML, and an encapsulation layer TFEL.

In an embodiment, the substrate SUB may be a base substrate or a base member. The substrate SUB may be a flexible substrate which can be bent, folded or rolled. For example, the substrate SUB may include a polymer resin such as polyimide (PI), but is not limited thereto. In another embodiment, the substrate SUB may include a glass material or a metal material.

In an embodiment, the thin film transistor layer TFTL may be disposed on the substrate SUB. The thin film transistor layer TFTL may include a plurality of thin film transistors constituting a pixel circuit of pixels. The thin film transistor layer TFTL may further include gate lines, data lines, power lines, gate control lines, fan-out lines that connect the display driver 200 to the data lines, and lead lines that connect the display driver 200 to the pad portion. Each of the thin film transistors may include a semiconductor region, a source electrode, a drain electrode, and a gate electrode. For example, when the gate driver is formed on one side of the non-display area NDA of the display panel 100, the gate driver may include thin film transistors.

The thin film transistor layer TFTL may be disposed in the display area DA, the non-display area NDA, and the sub-region SBA. Thin film transistors, gate lines, data lines, and power lines of each of the pixels of the thin film transistor layer TFTL may be disposed in the display area DA. Gate control lines and fan-out lines of the thin film transistor layer TFTL may be disposed in the non-display area NDA. The lead lines of the thin film transistor layer TFTL may be disposed in the sub-region SBA.

In an embodiment, the light emitting element layer EML may be disposed on the thin film transistor layer TFTL and may include a plurality of light emitting elements each including a first electrode, a second electrode, and a light emitting layer to emit light, and a pixel defining layer defining pixels. The plurality of light emitting elements of the light emitting element layer EML may be disposed in the display area DA.

In an embodiment, the light emitting layer may be an organic light emitting layer including an organic material. The light emitting layer may include a hole transporting layer, an organic light emitting layer, and an electron transporting layer. When the first electrode receives a voltage through the thin film transistor of the thin film transistor layer TFTL and the second electrode receives the cathode voltage, holes and electrons may be transferred to the organic light emitting layer through the hole transporting layer and the electron transporting layer, respectively and may be combined with each other to emit light in the organic light emitting layer.

In another embodiment, the light emitting elements may include a quantum dot light emitting diode including a quantum dot light emitting layer, an inorganic light emitting diode including an inorganic semiconductor, or a micro light emitting diode.

In an embodiment, the encapsulation layer TFEL may cover the top surface and the side surface of the light emitting element layer EML, and may protect the light emitting element layer EML. The encapsulation layer TFEL may include at least one inorganic layer and at least one organic layer for encapsulating the light emitting element layer EML.

In an embodiment, the touch sensing layer TSU may be disposed on the encapsulation layer TFEL and may include a plurality of touch electrodes for sensing a user's touch in a capacitive manner, and touch lines connecting the plurality of touch electrodes to the touch driver 400. For example, the touch sensing layer TSU may sense the user's touch by using a mutual capacitance method or a self-capacitance method.

In another embodiment, the touch sensing layer TSU may be disposed on a separate substrate disposed on the display layer DU. In this embodiment, the substrate supporting the touch sensing layer TSU may be a base member that encapsulates the display layer DU.

In an embodiment, the plurality of touch electrodes of the touch sensing layer TSU may be disposed in a touch sensor area overlapping the display area DA. The touch lines of the touch sensing layer TSU may be disposed in a touch peripheral area that overlaps the non-display area NDA.

In an embodiment, the color filter layer CFL may be disposed on the touch sensing layer TSU and may include a plurality of color filters corresponding to the plurality of emission areas. Each of the color filters may selectively transmit light of a specific wavelength and may block or absorb light of a different wavelength. The color filter layer CFL may absorb a part of light coming from the outside of the display device 10 to reduce reflected light due to external light. Accordingly, the color filter layer CFL may prevent color distortion caused by reflection of the external light.

Since the color filter layer CFL is directly disposed on the touch sensing layer TSU, the display device 10 may not require a separate substrate for the color filter layer CFL. Accordingly, the thickness of the display device 10 may be relatively small.

In an embodiment, the light blocking member layer PML may be disposed on the color filter layer CFL and may include light blocking patterns disposed to correspond to specific pixels of the display layer DU. The display device 10 may further include the light blocking member layer PML to control visibility at a specific viewing angle and provide a privacy protection mode to the user.

In an embodiment, the display device 10 may further include an optical device 500, where the optical device 500 may be disposed in the second display area DA2 or the third display area DA3. The optical device 500 may emit or receive light in infrared, ultraviolet, and visible light bands. For example, the optical device 500 may be an optical sensor that detects light incident on the display device 10 such as a proximity sensor, an illuminance sensor, and a camera sensor or an image sensor.

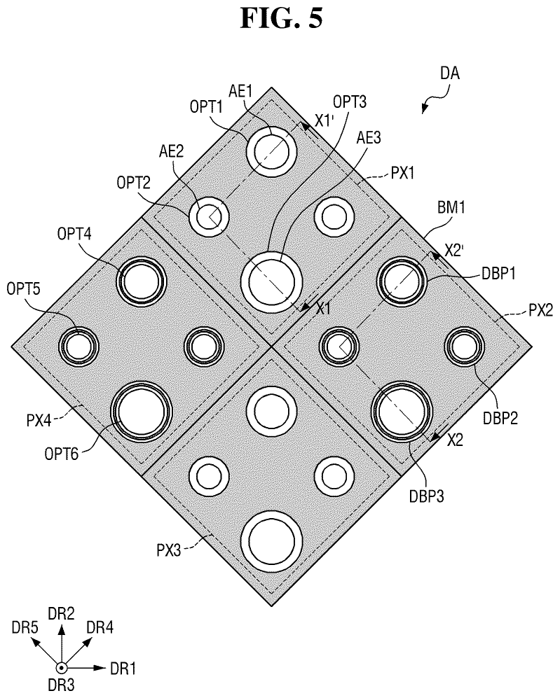

FIG. 4 is a plan view of the disposition of pixel electrodes in the display area of the display device, according to an embodiment. FIG. 5 is a plan view illustrating the disposition of a pixel electrode and a first light blocking layer in the display area of the display device, according to an embodiment.

In an embodiment and referring to FIGS. 4 and 5, the display device 10 may include a plurality of pixels PX1, PX2, PX3, and PX4 disposed in the display area DA. The plurality of pixels PX1, PX2, PX3, and PX4 may be arranged in a fourth direction DR4 and a fifth direction DR5, which are diagonal directions directed between the first direction DR1 and the second direction DR2. The first pixel PX1 and the second pixel PX2 may be disposed adjacent to each other in the fifth direction DR5, and the second pixel PX2 and the third pixel PX3 may be disposed adjacent to each other in the fourth direction DR4. The third pixel PX3 and the fourth pixel PX4 may be disposed adjacent to each other in the fifth direction DR5. The plurality of pixels PX1, PX2, PX3, and PX4 may be repeatedly disposed in the arrangement of FIG. 4 over the entire display area DA.

In an embodiment, each of the plurality of pixels PX1, PX2, PX3, and PX4 may include a plurality of pixel electrodes AE1, AE2, and AE3. For example, each of the plurality of pixels PX1, PX2, PX3, and PX4 may include a first pixel electrode AE1, a second pixel electrode AE2, and a third pixel electrode AE3. One pixel of the plurality of pixels PX1, PX2, PX3, PX4 may include one first pixel electrode AE1, two second pixel electrodes AE2, and one third pixel electrode AE3. However, the invention is not limited thereto. The number of the pixel electrodes AE1, AE2, and AE3 disposed in the pixels PX1, PX2, PX3, and PX4 may be variously modified.

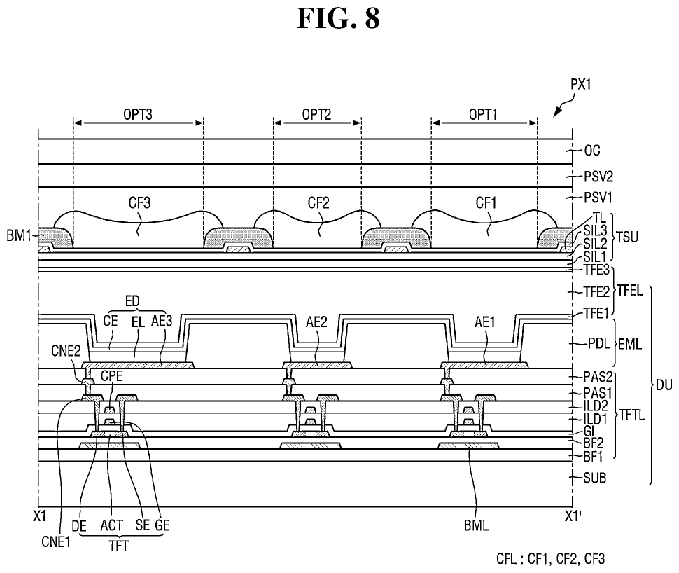

One pixel electrode AE1, AE2, AE3 may be an anode electrode of a light emitting element included in each of the pixels PX1, PX2, PX3, and PX4. One pixel of the plurality of pixels PX1, PX2, PX3, PX4 may include one or more light emitting elements ED (see FIG. 8), and the light emitting elements may be light emitting elements that emit light of different colors. For example, a light emitting element including the first pixel electrode AE1 may emit a first light of a red color. A light emitting element including the second pixel electrode AE2 may emit a second light of a green color, and a light emitting element including the third pixel electrode AE3 may emit a third light of a blue color. However, the invention is not limited thereto. One first pixel electrode AE1, two second pixel electrodes AE2, and one third pixel electrode AE3 may form one pixel of the plurality of pixels PX1, PX2, PX3, PX4, emit light of different colors, and express a white grayscale. However, the invention is not limited thereto, and the combination of the pixel electrodes AE1, AE2, and AE3 constituting one pixel of the plurality of pixels PX1, PX2, PX3, PX4 may be modified in various ways depending on the arrangement of the pixel electrodes AE1, AE2, and AE3, the color of light emitted by them, and the like.

Each of the pixel electrodes AE1, AE2, and AE3 may form an emission area in each of the pixels PX1, PX2, PX3, and PX4. For example, the first pixel electrode AE1 may form a first emission area that emits light of the first color, the second pixel electrode AE2 may form a second emission area that emits light of the second color, and the third pixel electrode AE3 may form a third emission area that emits light of the third color. In an embodiment, the emission area of the display device 10 may be an area overlapping the pixel electrodes AE1, AE2, and AE3, and for example, an opening of a pixel defining layer PDL (see FIG. 8) illustrated in FIG. 8 may correspond to the emission area. For example, the emission areas may be defined by the plurality of openings formed in the pixel defining layer PDL (see FIG. 8) of the light emitting element layer EML to be described later. The first emission area may be defined by a first opening of the pixel defining layer overlapping the first pixel electrode AE1, the second emission area may be defined by a second opening of the pixel defining layer overlapping the second pixel electrode AE2, and the third emission area may be defined by a third opening of the pixel defining layer overlapping the third pixel electrode AE3.

The plurality of pixel electrodes AE1, AE2, and AE3 may be disposed in a PenTile™ type, e.g., a diamond PenTile™ type. For example, the first pixel electrode AE1 and the third pixel electrode AE3 may be spaced apart from each other in the second direction DR2, and they may be alternately disposed in the first direction DR1 and the second direction DR2. The second pixel electrode AE2 may be spaced apart from another adjacent second pixel electrode AE2 in the first direction DR1 and the second direction DR2, and may be spaced apart from the adjacent first pixel electrode AE1 and the adjacent third pixel electrode AE3 in the fourth direction DR4 or the fifth direction DR5. The plurality of second pixel electrodes AE2 may be repeatedly disposed along the first direction DR1 and the second direction DR2, and the second pixel electrode AE2 and the first pixel electrode AE1, or the second pixel electrode AE2 and the third pixel electrode AE3 may be alternately disposed along the fourth direction DR4 or the fifth direction DR5.

In an embodiment, the areas or sizes of the first to third pixel electrodes may be different from each other. In the embodiment of FIG. 4, the area of the third pixel electrode AE3 may be larger than those of the first pixel electrode AE1 and the second pixel electrode AE2, and the area of the first pixel electrode AE1 may be larger than that of the second pixel electrode AE2. The intensity of emitted light may vary depending on the sizes of the emission areas overlapping the pixel electrodes AE1, AE2, and AE3, and the color displayed on the screen of the display device 10 or the electronic device 1 may be controlled by adjusting the size of the emission area. In the embodiment of FIG. 4, the third pixel electrode AE3 has the largest area, but is not limited thereto. The size of the pixel electrodes AE1, AE2, and AE3 and the area of the emission area may be freely adjusted according to the color of the screen required for the display device 10 and the electronic device 1. In addition, the areas of the pixel electrodes AE1, AE2, and AE3 may be related to light efficiency and the lifespan of the light emitting element ED (See FIG. 8), and may have a trade-off relation with the reflection by external light. The areas of the pixel electrodes AE1, AE2, and AE3 may be adjusted in consideration of the above factors.

In an embodiment, the display device 10 may include a first light blocking layer BM1 and a plurality of color filters CF1, CF2, and CF3 disposed on the pixel electrodes AE1, AE2, and AE3.

The first light blocking layer BM1 may be disposed over the entire display area DA and may include a plurality of holes disposed to correspond to the plurality of pixel electrodes AE1, AE2, and AE3. Each of the holes of the first light blocking layer BM1 may be disposed to correspond to the opening of the pixel defining layer PDL (see FIG. 8). The first light blocking layer BM1 may cover the display area DA except for an area where the holes are disposed in the display area DA. The holes of the first light blocking layer BM1 may be regions where lights emitted from the light emitting element including the pixel electrodes AE1, AE2, and AE3 are emitted.

In an embodiment, the plurality of holes may include, in the first pixel PX1, a first hole OPT1 overlapping the first pixel electrode AE1, a second hole OPT2 overlapping the second pixel electrode AE2, and a third hole OPT3 overlapping the third pixel electrode AE3. One first hole OPT1, two second holes OPT2, and one third hole OPT3 may be formed in the first light blocking layer BM1 within the area occupied by one first pixel PX1.

Each of the plurality of holes may have a larger area in a plan view than each of the pixel electrodes AE1, AE2, and AE3. For example, the first hole OPT1 of the first pixel PX1 may have a larger area in a plan view than the first pixel electrode AE1. The areas of the second hole OPT2 and the third hole OPT3 may also be larger than the areas of the second pixel electrode AE2 and the third pixel electrode AE3, respectively, in a plan view. In addition, the holes OPT1, OPT2, and OPT3 of the first light blocking layer BM1 may have different areas in a plan view. As described above, the areas of the plurality of pixel electrodes AE1, AE2, and AE3 may be different from each other, and accordingly, the sizes of the holes OPT1, OPT2, and OPT3 of the first light blocking layer BM1 may also be different from each other. For example, the diameter or size of the third hole OPT3 may be larger than those of the first hole OPT1 and the second hole OPT2, and the diameter or size of the first hole OPT1 may be larger than that of the second hole OPT2. However, the invention is not limited thereto.

In an embodiment, in the pixels PX1 and PX2 of the same type, the difference between the diameters of the pixel electrodes AE1, AE2, and AE3 and the diameters of the holes OPT1, OPT2, and OPT3 of the first light blocking layer BM1, or the separation distance between the outer sides of the pixel electrodes AE1, AE2, and AE3 and the inner sides of the holes OPT1, OPT2, and OPT3 may be uniform regardless of the types of the pixel electrodes AE1, AE2, and AE3 or the holes OPT1, OPT2, and OPT3. For example, the separation distance between the first pixel electrode AE1 and the first hole OPT1, or the difference between the diameter of the first pixel electrode AE1 and the diameter of the first hole OPT1 may be equal to the separation distance between the second pixel electrode AE2 and the second hole OPT2, or the difference between the diameter of the second pixel electrode AE2 and the diameter of the second hole OPT2. This may also be equal to the separation distance between the third pixel electrode AE3 and the third hole OPT3, or the difference between the diameter of the third pixel electrode AE3 and the diameter of the third hole OPT3. However, the invention is not limited thereto, and the separation distances between the pixel electrodes AE1, AE2, and AE3 and the holes OPT1, OPT2, and OPT3 of the first light blocking layer BM1 may be different depending on the type of the pixel electrodes AE1, AE2, and AE3.

In accordance with an embodiment, the display device 10 may include different types of the pixels PX1, PX2, PX3, and PX4 in which the holes of the first light blocking layer BM1 have different sizes. For example, in the first pixel PX1 and the third pixel PX3, the holes OPT1, OPT2, and OPT3 of the first light blocking layer BM1 may have the same diameter. Also, in the second pixel PX2 and the fourth pixel PX4, holes OPT4, OPT5, and OPT6 of the first light blocking layer BM1 may have the same diameter. However, in the first pixel PX1 and the second pixel PX2, the holes (e.g., the holes OPT1 and OPT4) of the first light blocking layer BM1 of the same type may have different diameters.

For example, in an embodiment, the plurality of holes of the first light blocking layer BM1 may include a fourth hole OPT4 overlapping the first pixel electrode AE1, a fifth hole OPT5 overlapping the second pixel electrode AE2, and a sixth hole OPT6 overlapping the third pixel electrode AE3 in the second pixel PX2. One fourth hole OPT4, two fifth holes OPT5, and one sixth hole OPT6 may be formed in the first light blocking layer BM1 within the area occupied by one second pixel PX2.

The fourth hole OPT4 of the second pixel PX2 may have a larger area in a plan view than the first pixel electrode AE1. The fifth hole OPT5 and the sixth hole OPT6 may also have larger areas in a plan view than the second pixel electrode AE2 and the third pixel electrode AE3, respectively. The diameter or size of the sixth hole OPT6 may be larger than that of the fourth hole OPT4 and the fifth hole OPT5, and the diameter or size of the fourth hole OPT4 may be larger than that of the fifth hole OPT5. However, the invention is not limited thereto.

In accordance with an embodiment, the pixel electrodes AE1, AE2, and AE3 of the same type in the first pixel PX1 and the second pixel PX2 may have the same diameter, whereas the holes corresponding to the pixel electrodes AE1, AE2, and AE3 of the same type in the first pixel PX1 and the second pixel PX2 may have different diameters. For example, the diameter of the first hole OPT1 corresponding to the first pixel electrode AE1 of the first pixel PX1 may be larger than that of the fourth hole OPT4 corresponding to the first pixel electrode AE1 of the second pixel PX2. The diameter of the second hole OPT2 corresponding to the second pixel electrode AE2 of the first pixel PX1 may be larger than that of the fifth hole OPT5 corresponding to the second pixel electrode AE2 of the second pixel PX2. The diameter of the third hole OPT3 corresponding to the third pixel electrode AE3 of the first pixel PX1 may be larger than that of the sixth hole OPT6 corresponding to the third pixel electrode AE3 of the second pixel PX2. In the different pixels PX1 and PX2, the pixel electrodes AE1, AE2, and AE3 may have the same diameter, but the holes may have different diameters, and the separation distances between the pixel electrodes AE1, AE2, and AE3 and the holes may be different from each other.

According to an embodiment, the display device 10 may include the pixels PX1, PX2, PX3, and PX4 having different separation distances between the pixel electrodes AE1, AE2, and AE3 and the holes of the first light blocking layer BM1. For example, in the first pixel PX1 and the third pixel PX3, the separation distances between the pixel electrodes AE1, AE2, and AE3 and the holes OPT1, OPT2, and OPT3 of the first light blocking layer BM1 may be equal to each other. Also, in the second pixel PX2 and the fourth pixel PX4, the separation distances between the pixel electrodes AE1, AE2, and AE3 and the holes OPT4, OPT5, and OPT6 of the first light blocking layer BM1 may be equal to each other. However, in the first pixel PX1 and the second pixel PX2, the separation distances between the pixel electrodes AE1, AE2, and AE3 and the holes OPT1 to OPT3 and OPT4 to OPT6 of the first light blocking layer BM1 may be different from each other. In an embodiment, the separation distance between the pixel electrodes AE1, AE2, and AE3 and the holes OPT1, OPT2, and OPT3 of the first light blocking layer BM1 in the first pixel PX1 and the third pixel PX3 may be larger than the separation distance between the pixel electrodes AE1, AE2, and AE3 and the holes OPT4, OPT5, and OPT6 of the first light blocking layer BM1 in the second pixel PX2 and the fourth pixel PX4. In the second pixel PX2 and the fourth pixel PX4, the difference in diameter between the pixel electrodes AE1, AE2, and AE3 and the holes OPT4, OPT5, and OPT6 of the first light blocking layer BM1 may be small, and the outer sides of the pixel electrodes AE1, AE2, and AE3 and the inner sides of the holes OPT1, OPT2, and OPT3 may be located adjacent to each other in a plan view.

In accordance with an embodiment, the first light blocking layer BM1 may include a plurality of divided portions DBP1, DBP2, and DBP3 disposed in a second type pixel, e.g., the second pixel PX2 and the fourth pixel PX4. The divided portions DBP1, DBP2, and DBP3 may be formed to penetrate the first light blocking layer BM1 in a similar fashion to the hole of the first light blocking layer BM1. The divided portions DBP1, DBP2, and DBP3 may be disposed around the holes OPT4, OPT5, and OPT6 of the first light blocking layer BM1 located in the second pixel PX2, and in some embodiments, the divided portions DBP1, DBP2, and DBP3 may surround the holes OPT4, OPT5, and OPT6 of the first light blocking layer BM1.

For example, the divided portions DBP1, DBP2, and DBP3 may include the first divided portion DBP1 disposed to surround the fourth hole OPT4, the second divided portion DBP2 disposed to surround the fifth hole OPT5, and the third divided portion DBP3 disposed to surround the sixth hole OPT6 in the second pixel PX2. The plurality of divided portions DBP1, DBP2, and DBP3 may have predetermined widths and surround the pixel electrodes AE1, AE2, and AE3 or the holes OPT4, OPT5, and OPT6. Separated patterns of the first light blocking layer BM1 may remain between the holes OPT4, OPT5, and OPT6 and the divided portions DBP1, DBP2, and DBP3.

In an embodiment, since the plurality of divided portions DBP1, DBP2, and DBP3 are formed to surround the holes OPT4, OPT5, and OPT6, respectively, the different divided portions DBP1, DBP2, and DBP3 may have different sizes. For example, the diameter of the portion surrounded by the first divided portion DBP1 may be larger than that of the portion surrounded by the second divided portion DBP2, and may be smaller than that of the portion surrounded by the third divided portion DBP3. The size relationship thereof may be the same as that of the diameters of the holes OPT4, OPT5, and OPT6, or the diameters of the pixel electrodes AE1, AE2, and AE3.

In the first light blocking layer BM1, the diameters of the holes OPT1, OPT2, and OPT3 disposed in the first pixel PX1 and the diameters of the holes OPT4, OPT5, and OPT6 disposed in the second pixel PX2 may be different from each other. Accordingly, the distance between two adjacent holes, or the width of the pattern of the first light blocking layer BM1 may be different in the first pixel PX1 and the second pixel PX2. For example, the distance between the first hole OPT1 and the second hole OPT2 in the first pixel PX1 may be smaller than that between the fourth hole OPT4 and the fifth hole OPT5 in the second pixel PX2. As will be described later, the color filters CF1, CF2, and CF3 may be disposed on the first light blocking layer BM1, and the thicknesses of the color filters CF1, CF2, and CF3 may vary depending on the width of the pattern of the first light blocking layer BM1. Since the distance between two adjacent holes OPT1, OPT2, and OPT3 in the first pixel PX1 is smaller than that between two adjacent holes OPT4, OPT5, and OPT6 in the second pixel PX2, the thicknesses of the color filters CF1, CF2, and CF3 disposed in the first pixel PX1 may be smaller than those of the color filters CF1, CF2, and CF3 disposed in the second pixel PX2.

Since the thicknesses of the color filters CF1, CF2, and CF3 disposed in the second pixel PX2 are thicker, the transmittance of light may decrease. In an embodiment, the plurality of divided portions DBP1, DBP2, and DBP3 may be disposed around the holes OPT4, OPT5, and OPT6 of the second pixel PX2 and may serve to reduce the thicknesses of the color filters CF1, CF2, and CF3. The color filters CF1, CF2, and CF3 may be disposed to cover all the plurality of holes and the divided portions DBP1, DBP2, and DBP3, and may have reduced thicknesses by filling the spaces formed by the plurality of divided portions DBP1, DBP2, and DBP3. Accordingly, the thickness difference between the color filters CF1, CF2, and CF3 in the first pixel PX1 and the second pixel PX2 may be reduced, and the light transmittance difference between the two pixels may be reduced. A more detailed description will be given later.

In an embodiment, the display device 10 may include a first type pixel such as the first pixel PX1 and the third pixel PX3, and a second type pixel such as the second pixel PX2 and the fourth pixel PX4. The first type pixel and the second type pixel may be distinguished according to the separation distance between the pixel electrodes AE1, AE2, and AE3 and the hole of the first light blocking layer BM1, or the diameter difference of holes, and the disposition of a second light blocking layer BM2 to be described later as well as the disposition of the divided portions DBP1, DBP2, and DBP3. For example, the second light blocking layer BM2 may not be disposed in the first pixel PX1 and the third pixel PX3, and the second light blocking layer BM2 may be disposed in the second pixel PX2 and the fourth pixel PX4.

In an embodiment, the plurality of color filters CF1, CF2, and CF3 (see FIG. 8) may be disposed to respectively correspond to the pixel electrodes AE1, AE2, and AE3. For example, the color filters CF1, CF2, and CF3 may be disposed on the first light blocking layer BM1 and may be disposed to correspond to the plurality of holes in the first light blocking layer BM1. The holes of the first light blocking layer BM1 may be formed to overlap the opening of the pixel defining layer PDL (see FIG. 8), and may form a light exit area through which light emitted from the emission area is emitted. The color filters CF1, CF2, and CF3 may have areas larger than those of the holes of the first light blocking layer BM1, and the color filters CF1, CF2, and CF3 may completely cover the light exit area formed by the holes. The color filters CF1, CF2, and CF3 may completely cover the holes of the first light blocking layer BM1, and some of them may be directly disposed on the first light blocking layer BM1. However, in an embodiment, the color filters CF1, CF2, and CF3 may be omitted.

In an embodiment, the color filters CF1, CF2, and CF3 may include the first color filter CF1, the second color filter CF2, and the third color filter CF3 disposed to correspond to the different pixel electrodes AE1, AE2, and AE3, respectively. The color filters CF1, CF2, and CF3 may include a colorant such as a dye or pigment that absorbs light in a wavelength band different from light in a specific wavelength band, and may be disposed to correspond to the color of light emitted by a light emitting element including the pixel electrodes AE1, AE2, and AE3. For example, the first color filter CF1 may be a red color filter that is disposed to overlap the first pixel electrode AE1 and may transmit only the first light of the red color. The second color filter CF2 may be a green color filter that is disposed to overlap the second pixel electrode AE2 and may transmit only the second light of the green color, and the third color filter CF3 may be a blue color filter that is disposed to overlap the third pixel electrode AE3 and may transmit only the third light of the blue color.

Similarly to the disposition of the pixel electrodes AE1, AE2, and AE3, the color filters CF1, CF2, and CF3 may be disposed in a PenTile™ type, e.g., a diamond PenTile™ type. For example, the first color filter CF1 and the third color filter CF3 may be alternately disposed in the first direction DR1 and the second direction DR2. The second color filter CF2 and another adjacent second color filter CF2 may be arranged in the first direction DR1 and the second direction DR2, and the second color filter CF2 and the adjacent first color filter CF1 and the adjacent third color filter CF3 may be arranged in the fourth direction DR4 or the fifth direction DR5. The plurality of second color filters CF2 may be repeatedly disposed along the first direction DR1 and the second direction DR2, and the second color filter CF2 and the first color filter CF1, or the second color filter CF2 and the third color filter CF3 may be alternately disposed along the fourth direction DR4 or the fifth direction DR5.

According to an embodiment, the plurality of color filters CF1, CF2, and CF3 may have different areas in a plan view. As described above, the areas of the plurality of pixel electrodes AE1, AE2, and AE3 may be different from each other, and accordingly, the sizes of the holes of the first light blocking layer BM1, and the areas of the color filters CF1, CF2, and CF3 in a plan view may also be different from each other. For example, the area of the first color filter CF1, which is a red color filter, may be larger than the area of the second color filter CF2, which is a green color filter, and the area of the third color filter CF3, which is a blue color filter. Additionally, the area of the third color filter CF3 may be larger than the area of the second color filter CF2. The shape of the color filters CF1, CF2, and CF3 in a plan view may be a circular shape similar to the shape of the pixel electrodes AE1, AE2, and AE3. However, the invention is not limited thereto, and the color filters CF1, CF2, and CF3 may have a rectangular or rhombic shape in a plan view. The display device 10 according to an embodiment may be designed such that the planar shape and area of the color filters CF1, CF2, and CF3 allow external light of the display device 10 to have a specific color.

In an embodiment, the planar area ratio of the first color filter CF1 and the second color filter CF2 may be in a range of about 1:0.3 to about 1:0.7, and the area ratio of the first color filter CF1 and the third color filter CF3 may be in a range of about 1:0.4 to about 1:1. For example, the area ratio of the first color filter CF1, the second color filter CF2, and the third color filter CF3 may be about 1:0.59:0.52 or about 1:0.59:1. However, the area ratio of the color filters CF1, CF2, and CF3 is not limited to the above-described, and the planar areas of the color filters CF1, CF2, and CF3 may be designed differently such that the reflected light in the display device 10 and the electronic device 1 has desired color coordinates.

In an embodiment, the display device 10 may include the color filters CF1, CF2, and CF3 disposed on the display layer DU to reduce the intensity of reflected light caused by external light. Furthermore, the color of the reflected light by the external light may be controlled by adjusting the disposition, shape, and area of the color filters CF1, CF2, and CF3 in a plan view.

In an embodiment, a touch electrode TL may be disposed between the pixel electrodes AE1, AE2, and AE3. The touch electrode TL may be disposed to extend in the fourth direction DR4 and the fifth direction DR5, and may be spaced apart from the pixel electrodes AE1, AE2, and AE3. The touch electrode TL may be disposed to overlap the pixel defining layer PDL (see FIG. 8) and the first light blocking layer BM1. Although the touch electrode TL is briefly illustrated in the drawing, the touch electrode TL may include a touch driving electrode and a sensing electrode.

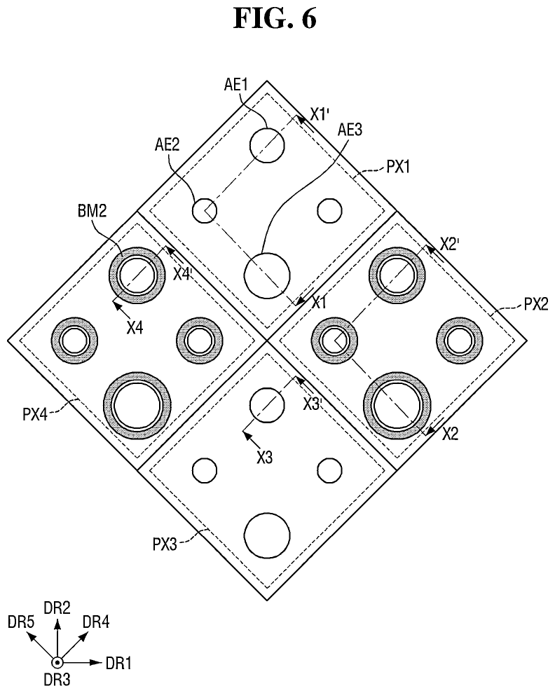

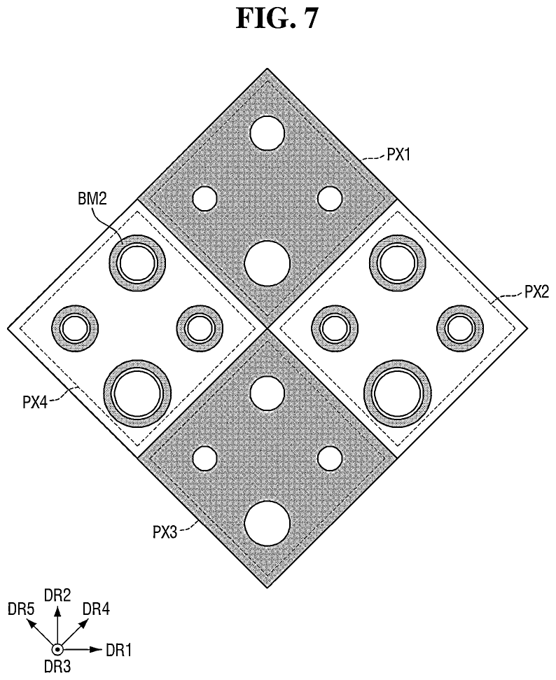

FIG. 6 is a plan view illustrating the disposition of a pixel electrode and a second light blocking layer in the display area of the display device, according to an embodiment. FIG. 7 is a schematic diagram illustrating light emitting pixels according to an emission mode of the display device, according to an embodiment. FIG. 7 schematically illustrates the light emitting pixels in an emission mode with partially restricted side visibility among the emission modes of the display device 10.

In an embodiment and referring to FIGS. 6 and 7, the display device 10 may include the second light blocking layer BM2. The second light blocking layer BM2 may be disposed only in some of the plurality of pixels in the display area DA. For example, the second light blocking layer BM2 may be disposed in the second type pixel, e.g., the second pixel PX2 and the fourth pixel PX4, of the plurality of pixels PX. As described above, the plurality of pixels PX may include two types of pixels in which the pixel electrodes AE1, AE2, and AE3 and the holes of the first light blocking layer BM1 have different thicknesses, and the second light blocking layer BM2 may be disposed only in the second type pixel.

In an embodiment, the second light blocking layer BM2 may include a plurality of light blocking patterns, and the light blocking patterns may be disposed to correspond to the plurality of pixel electrodes AE1, AE2, and AE3. For example, the light blocking patterns may each have a uniform width and may be disposed to surround the pixel electrodes AE1, AE2, and AE3 without overlapping the pixel electrodes AE1, AE2, and AE3 in a plan view. The light blocking patterns may have a circular ring shape that surrounds the pixel electrodes AE1, AE2, and AE3 without covering them in plan view. Similarly to the hole of the first light blocking layer BM1, the inner sides of the light blocking patterns may be spaced apart from the outer sides of the pixel electrodes AE1, AE2, and AE3 in a plan view.

In the display device 10, according to an embodiment, the plurality of pixels PX may include the first type pixel in which the second light blocking layer BM2 is not disposed and the second type pixel in which the second light blocking layer BM2 is disposed, so that the side visibility may be adjusted depending on the emission mode. Depending on the viewing angle of the display device 10, the light blocking patterns of the second light blocking layer BM2 may partially cover the pixel electrodes AE1, AE2, and AE3, and may block the emission of light at a specific viewing angle.

For example, in an embodiment, in a first emission mode of the display device 10, when the side visibility is not restricted, both the first type pixel and the second type pixel may emit light. For example, as shown in FIG. 6, when all of the pixels PX1, PX2, PX3, and PX4 emit light in the first emission mode, light emitted from at least the first pixel PX1 and the third pixel PX3 may be visually recognized by the user, regardless of which direction the user looks at the display device 10.

On the other hand, in an embodiment, in a second emission mode of the display device 10, when it is required to restrict the side visibility, only the second type pixel may emit light. For example, as illustrated in FIG. 7, when only the second pixel PX2 and the fourth pixel PX4 emit light in the second emission mode, light emitted from the holes OPT1, OPT2, and OPT3 of the first light blocking layer BM1 may be blocked by the second light blocking layer BM2 at a specific viewing angle. Since the first pixel PX1 and the third pixel PX3 do not emit light, the screen of the display device 10 in the second emission mode may be visually recognized only by the user looking from the front of the display area DA, and may not be visually recognized by the user looking from a specific viewing angle or from the side. The display device 10 may provide a privacy protection mode to the user.

In the second emission mode of the display device 10, a light leakage phenomenon of light emitted from the pixel electrodes AE1, AE2, and AE3 of the second pixel PX2 and the fourth pixel PX4 may occur depending on the extent to which they are covered by the second light blocking layer BM2. However, in the display device 10 according to an embodiment, the light blocking patterns of the second light blocking layer BM2 may be disposed to surround the pixel electrodes AE1, AE2, and AE3 in correspondence with the shape of the pixel electrodes AE1, AE2, and AE3. In the display device 10, the extent to which the pixel electrodes AE1, AE2, and AE3 of the second type pixel are covered may be uniform at all viewing angles looking at the display device 10 in the second emission mode, and it is possible to prevent the light leakage phenomenon of light emitted from the light emitting elements including the specific pixel electrodes AE1, AE2, and AE3.

In addition, in an embodiment, in the display device 10, since the light blocking patterns of the second light blocking layer BM2 are disposed to correspond to the pixel electrodes AE1, AE2, and AE3 of the second type pixel, they may not invade other adjacent pixels, e.g., the first type pixel, and thus may not cover the pixel electrode of the first type pixel in the first emission mode. That is, in the display device 10, the disposition of the pixel structure may be freely designed even in the implementation of a high-resolution display device.

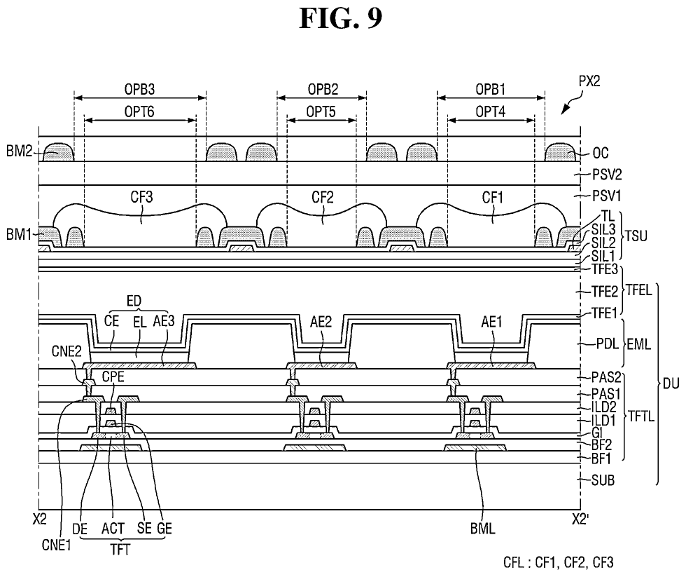

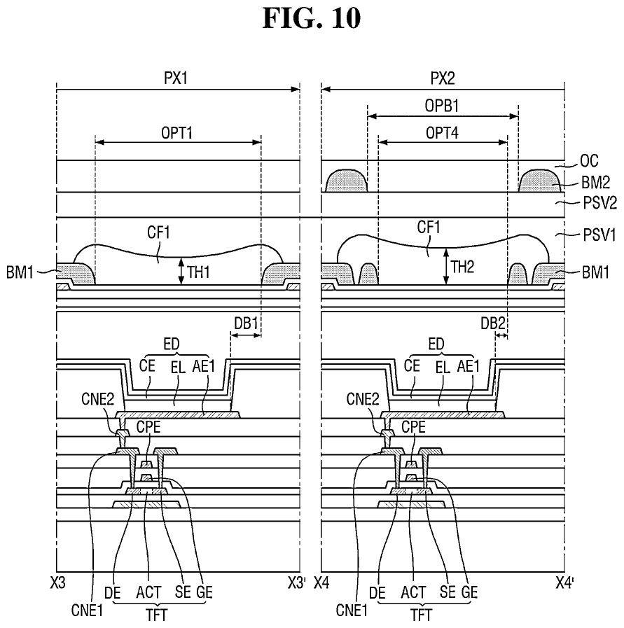

FIG. 8 is a cross-sectional view taken along line X1-X1′ of FIGS. 5 and 6, according to an embodiment. FIG. 9 is a cross-sectional view taken along line X2-X2′ of FIGS. 5 and 6, according to an embodiment. FIG. 10 is a cross-sectional view taken along lines X3-X3′ and X4-X4′ of FIGS. 5 and 6, according to an embodiment.

FIG. 8 shows a cross section across the pixel electrodes AE1, AE2, and AE3 in the first pixel PX1 which is the first type pixel. FIG. 9 shows a cross section across the pixel electrodes AE1, AE2, and AE3 in the second pixel PX2 which is the second type pixel. FIG. 10 shows a cross section across the first pixel electrode AE1 of the first type pixel and the first pixel electrode AE1 of the second type pixel.

A cross-sectional structure of the display device 10 will be described with reference to FIGS. 8 to 10. In an embodiment, the display panel 100 of the display device 10 may include the display layer DU, the touch sensing layer TSU, the first light blocking layer BM1, the color filter layer CFL, and the second light blocking layer BM2. The display layer DU may include the substrate SUB, the thin film transistor layer TFTL, the light emitting element layer EML, and the encapsulation layer TFEL. The first light blocking layer BM1 may be disposed on the touch sensing layer TSU of the display panel 100, and the color filters CF1, CF2, and CF3 of the color filter layer CFL may be disposed on the first light blocking layer BM1. The second light blocking layer BM2 may be disposed on passivation layers PSV1 and PSV2 disposed on the color filter layer CFL, and an overcoat layer OC may be disposed on the second light blocking layer BM2.

The substrate SUB may be a base substrate or a base member. The substrate SUB may be a flexible substrate which can be bent, folded or rolled. For example, the substrate SUB may include a polymer resin such as polyimide (PI), but is not limited thereto. In another embodiment, the substrate SUB may include a glass material or a metal material.

The thin film transistor layer TFTL may include a first buffer layer BF1, a lower metal layer BML, a second buffer layer BF2, a thin film transistor TFT, a gate insulating layer GI, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2.

The first buffer layer BF1 may be disposed on the substrate SUB and may include an inorganic layer capable of preventing penetration of air or moisture. For example, the first buffer layer BFI may include a plurality of inorganic layers alternately stacked.

The lower metal layer BML may be disposed on the first buffer layer BF1. For example, the lower metal layer BML may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

The second buffer layer BF2 may cover the first buffer layer BF1 and the lower metal layer BML and may include an inorganic layer capable of preventing penetration of air or moisture. For example, the second buffer layer BF2 may include a plurality of inorganic layers alternately stacked.

In an embodiment, the thin film transistor TFT may be disposed on the second buffer layer BF2, and may constitute a pixel circuit of each of a plurality of pixels. For example, the thin film transistor TFT may be a switching transistor or a driving transistor of the pixel circuit. The thin film transistor TFT may include a semiconductor layer ACT, a source electrode SE, a drain electrode DE, and a gate electrode GE.

The semiconductor layer ACT may be disposed on the second buffer layer BF2 and may overlap the lower metal layer BML and the gate electrode GE in the thickness direction, and may be insulated from the gate electrode GE by the gate insulating layer GI. In a part of the semiconductor layer ACT, a material of the semiconductor layer ACT may be made into a conductor to form the source electrode SE and the drain electrode DE.

The gate electrode GE may be disposed on the gate insulating layer GI and may overlap the semiconductor layer ACT with the gate insulating layer GI interposed therebetween.

The gate insulating layer GI may be disposed on the semiconductor layer ACT and may cover the semiconductor layer ACT and the second buffer layer BF2 to insulate the gate electrode GE from the semiconductor layer ACT. The gate insulating layer GI may include a contact hole through which the first connection electrode CNE1 passes.

In an embodiment, the first interlayer insulating layer ILD1 may cover the gate electrode GE and the gate insulating layer GI and may include a contact hole through which the first connection electrode CNE1 passes. The contact hole of the first interlayer insulating layer ILD1 may be connected to the contact hole of the gate insulating layer GI and the contact hole of the second interlayer insulating layer ILD2.

In an embodiment, the capacitor electrode CPE may be disposed on the first interlayer insulating layer ILD1 and may overlap the gate electrode GE in the thickness direction. The capacitor electrode CPE and the gate electrode GE may form a capacitance.

In an embodiment, the second interlayer insulating layer ILD2 may cover the capacitor electrode CPE and the first interlayer insulating layer ILD1 and may include a contact hole through which the first connection electrode CNE1 passes. The contact hole of the second interlayer insulating layer ILD2 may be connected to the contact hole of the first interlayer insulating layer ILD1 and the contact hole of the gate insulating layer GI.

The first connection electrode CNE1 may be disposed on the second interlayer insulating layer ILD2 and may electrically connect the drain electrode DE of the thin film transistor TFT to the second connection electrode CNE2. The first connection electrode CNE1 may be inserted into a contact hole provided in the second interlayer insulating layer ILD2, the first interlayer insulating layer ILD1, and the gate insulating layer GI to be in contact with the drain electrode DE of the thin film transistor TFT.

In an embodiment, the first passivation layer PAS1 may cover the first connection electrode CNE1 and the second interlayer insulating layer ILD2 and may protect the thin film transistor TFT. The first passivation layer PAS1 may include a contact hole through which the second connection electrode CNE2 passes.

The second connection electrode CNE2 may be disposed on the first passivation layer PAS1 and may electrically connect the first connection electrode CNE1 to a pixel electrode AE of the light emitting element ED. The second connection electrode CNE2 may be inserted into a contact hole formed in the first passivation layer PAS1 to be in contact with the first connection electrode CNE1.

In an embodiment, the second passivation layer PAS2 may cover the second connection electrode CNE2 and the first passivation layer PAS1 and may include a contact hole through which the pixel electrode AE of the light emitting element ED passes.

In an embodiment, the light emitting element layer EML may be disposed on the thin film transistor layer TFTL and may include the light emitting element ED and the pixel defining layer PDL. The light emitting element ED may include the pixel electrodes AE1, AE2, and AE3, a light emitting layer EL, and a common electrode CE.

The pixel electrodes AE1, AE2, and AE3 may be disposed on the second passivation layer PAS2. Each of the different pixel electrodes AE1, AE2, and AE3 may be disposed to overlap one of the different openings of the pixel defining layer PDL. The pixel electrodes AE1, AE2, and AE3 may be electrically connected to the drain electrode DE of the thin film transistor TFT through the first and second connection electrodes CNE1 and CNE2.

In an embodiment, the light emitting layer EL may be disposed on the pixel electrodes AE1, AE2, and AE3. For example, the light emitting layer EL may be an organic light emitting layer made of an organic material, but is not limited thereto. In the case of employing the organic light emitting layer as the light emitting layer EL, the thin film transistor TFT applies a predetermined voltage to the pixel electrodes AE1, AE2, and AE3 of the light emitting element ED, and if the common electrode CE of the light emitting element ED receives a common voltage or a cathode voltage, the holes and electrons can move to the light emitting layer EL through the hole transporting layer and the electron transporting layer and combine to produce light to be emitted by the light emitting layer EL.

In an embodiment, the light emitting layers EL disposed on different pixel electrodes AE1, AE2, and AE3 may emit light of different colors. For example, the light emitting layer disposed on the first pixel electrode AE1 may emit red light of the first color, the light emitting layer disposed on the second pixel electrode AE2 may emit green light of the second color, and the light emitting layer disposed on the third pixel electrode AE3 may emit blue light of the third color. However, the invention is not limited thereto. In another embodiment, the light emitting layer EL may be disposed as a single common layer on the different pixel electrodes AE1, AE2, and AE3 and the pixel defining layer PDL, and the light emitting layer EL disposed on the different pixel electrodes AE1, AE2, and AE3 may emit light of the same color. In this case, the display device 10 may further include a color adjustment layer disposed on the light emitting elements ED.

In an embodiment, the common electrode CE may be arranged on the light emitting layer EL. For example, the common electrode CE may be made in the form of an electrode common to all of the pixels rather than specific to each of the pixels. The common electrode CE may be disposed on the light emitting layer EL in the pixel electrodes AE1, AE2, and AE3, and may be disposed on the pixel defining layer PDL in an area other than the pixel electrodes AE1, AE2, and AE3.

The common electrode CE may receive the common voltage or a low potential voltage. When the pixel electrode AE receives a voltage corresponding to a data voltage and the common electrode CE receives the low potential voltage, a potential difference is formed between the pixel electrodes AE1, AE2, and AE3 and the common electrode CE, so that the light emitting layer EL may emit light.

In an embodiment, the pixel defining layer PDL may include a plurality of openings and may be disposed on a part of the pixel electrodes AE1, AE2, and AE3 and the second passivation layer PAS2. Each opening of the pixel defining layer PDL may partially expose the pixel electrodes AE1, AE2, and AE3. As described above, the respective openings of the pixel defining layer PDL may define the first to third emission areas, and the areas or sizes thereof may be different from each other. The pixel defining layer PDL may separate and insulate the pixel electrodes AE1, AE2, and AE3 of each of the plurality of light emitting elements ED. The pixel defining layer PDL may include a light absorbing material to prevent light reflection. For example, the pixel defining layer PDL may include a polyimide (PI)-based binder and a pigment in which red, green, and blue colors are mixed. In another embodiment, the pixel defining layer PDL may include a cardo-based binder resin and a mixture of a lactam black pigment and a blue pigment. In still another embodiment, the pixel defining layer PDL may include carbon black.

In an embodiment, the encapsulation layer TFEL may be disposed on the common electrode CE to cover the plurality of light emitting elements ED. The encapsulation layer TFEL may include at least one inorganic layer to prevent oxygen or moisture from penetrating into the light emitting element layer EML. The encapsulation layer TFEL may include at least one organic layer to protect the light emitting element layer EML from foreign matters such as dust.

In an embodiment, the encapsulation layer TFEL may include a first encapsulation layer TFE1, a second encapsulation layer TFE2, and a third encapsulation layer TFE3. The first encapsulation layer TFE1 and the third encapsulation layer TFE3 may be inorganic encapsulation layers, and the second encapsulation layer TFE2 disposed between the first encapsulation layer TFE1 and the third encapsulation layer TFE3 may be an organic encapsulation layer.

Each of the first encapsulation layer TFE1 and the third encapsulation layer TFE3 may include one or more inorganic insulating materials. The inorganic insulating material may include aluminum oxide, titanium oxide, tantalum oxide, hafnium oxide, zinc oxide, silicon oxide, silicon nitride, and/or silicon oxynitride.

The second encapsulation layer TFE2 may include a polymer-based material. Examples of the polymer-based material may include acrylic resin, epoxy resin, polyimide, polyethylene and the like. For example, the second encapsulation layer TFE2 may include an acrylic resin, for example, polymethyl methacrylate, polyacrylic acid, or the like. The second encapsulation layer TFE2 may be formed by curing a monomer or applying a polymer.

In an embodiment, the touch sensing layer TSU may be disposed on the encapsulation layer TFEL and may include a first touch insulating layer SIL1, a second touch insulating layer SIL2, the touch electrode TL, and a third touch insulating layer SIL3.

The first touch insulating layer SIL1 may be disposed on the encapsulation layer TFEL. The first touch insulating layer SIL1 may have an insulating and optical function. The first touch insulating layer SIL1 may include at least one inorganic layer. In another embodiment, the first touch insulating layer SIL1 may be omitted.

The second touch insulating layer SIL2 may cover the first touch insulating layer SIL1. Although not illustrated in the drawings, a touch electrode of another layer may be further disposed on the first touch insulating layer SIL1, and the second touch insulating layer SIL2 may cover the touch electrode TL. The second touch insulating layer SIL2 may have an insulating and optical function. For example, the second touch insulating layer SIL2 may be an inorganic layer containing at least one of a silicon nitride layer, a silicon oxynitride layer, a silicon oxide layer, a titanium oxide layer, or an aluminum oxide layer.

A part of the touch electrode TL may be disposed on the second touch insulating layer SIL2. The touch electrode TL may not overlap the pixel electrodes AE1, AE2, and AE3. The touch electrode TL may be formed of a single layer containing molybdenum (Mo), titanium (Ti), copper (Cu), aluminum (Al), or indium tin oxide (ITO), or may be formed to have a stacked structure (Ti/Al/Ti) of aluminum and titanium, a stacked structure (ITO/AI/ITO) of aluminum and ITO, an Ag—Pd—Cu (APC) alloy, or a stacked structure (ITO/APC/ITO) of APC alloy and ITO.

The touch electrode TL of the touch sensing layer TSU may have a constant line width and may be disposed to overlap the first light blocking layer BM1, which will be described later. The first light blocking layer BM1 may have a width sufficient to completely cover the touch electrode TL, and a gap between an edge of the first light blocking layer BM1 and the touch electrode TL may be defined. In an embodiment, the line width of the touch electrode TL may be in a range of about 4 μm to about 6 μm, and the gap between the touch electrode TL and the edge of the first light blocking layer BM1 may be in a range of about 5 μm to about 7 μm. The touch electrode TL may be disposed such that its center is substantially aligned with the center of the first light blocking layer BM1, and the gap from both sides of the touch electrode TL to the edge of the first light blocking layer BM1 may be substantially constant.

The third touch insulating layer SIL3 may cover the touch electrode TL and the second touch insulating layer SIL2. The third touch insulating layer SIL3 may have an insulating and optical function. The third touch insulating layer SIL3 may be made of the material exemplified in association with the second touch insulating layer SIL2.

In an embodiment, the first light blocking layer BM1 may be disposed on the third touch insulating layer SIL3 of the touch sensing layer TSU. The first light blocking layer BM1 may be disposed to cover the conductive line of the touch electrode TL, while including the plurality of holes OPT1, OPT2, OPT3, OPT4, OPT5, and OPT6 that overlap the pixel electrodes AE1, AE2, and AE3. For example, the first hole OPT1 may be disposed to overlap the first pixel electrode AE1 of the first pixel PX1. The second hole OPT2 may be disposed to overlap the second pixel electrode AE2 of the first pixel PX1, and the third hole OPT3 may be disposed to overlap the third pixel electrode AE3 of the first pixel PX1. The fourth hole OPT4 may be disposed to overlap the first pixel electrode AE1 of the second pixel PX2. The fifth hole OPT5 may be disposed to overlap the second pixel electrode AE2 of the second pixel PX2, and the sixth hole OPT6 may be disposed to overlap the third pixel electrode AE3 of the second pixel PX2. The area or size of each of the holes OPT1, OPT2, OPT3, OPT4, OPT5, and OPT6 may be larger than the areas or sizes of the pixel electrodes AE1, AE2, and AE3. In addition, the area or size of each of the holes OPT1, OPT2, and OPT3 may be formed to be larger than that of the corresponding opening of the pixel defining layer PDL, and light emitted from the light emitting element ED may be visually recognized by the user not only from the front of the display device 10 but also from the side thereof. However, whether or not the first pixel PX1 and the second pixel PX2 emit light may vary depending on the emission mode of the display device 10, and the shape of the first light blocking layer BM1 may be designed such that light is not visually recognized at a specific viewing angle in the emission mode in which side visibility is restricted in the second pixel PX2.

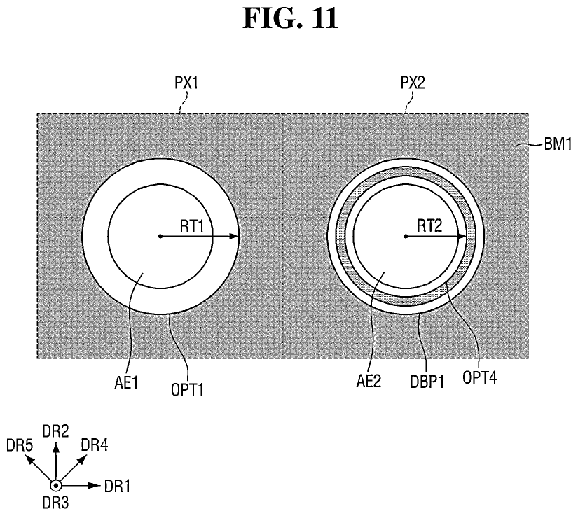

FIG. 11 is a diagram illustrating the relative disposition of a pixel electrode and a first light blocking layer disposed in one pixel of the display device, according to an embodiment. FIG. 11 illustrates the planar disposition of the first pixel electrode AE1 and the first hole OPT1 of the first pixel PX1, and the first pixel electrode AE1, the fourth hole OPT4, and the first divided portion DBP1 of the second pixel PX2.

In an embodiment and referring further to FIG. 11, in the display device 10, the sizes of the holes OPT1, OPT2, and OPT3 disposed in the first pixel PX1 may be larger than those of the holes OPT4, OPT5, and OPT6 disposed in the second pixel PX2. For example, a radius RT1, or the size of the first hole OPT1 overlapping the first pixel electrode AE1 of the first pixel PX1 may be larger than a radius RT2, or the size of the fourth hole OPT4 overlapping the first pixel electrode AE1 of the second pixel PX2.

Although not shown in FIG. 11, in an embodiment and as described above, the radius, or the size of the second hole OPT2 in the first pixel PX1 may be larger than the radius, or the size of the fifth hole OPT5 in the second pixel PX2. The radius, or the size of the third hole OPT3 in the first pixel PX1 may be larger than the radius, or the size of the sixth hole OPT6 in the second pixel PX2.

In the second emission mode of the display device 10, the first type pixel may not emit light, and only the second type pixel may emit light. When the second type pixel emits light, the size of the holes OPT4, OPT5, and OPT6 of the first light blocking layer BM1 in the second pixel PX2 may be relatively small to block light from exiting at a specific viewing angle. Further, since the second light blocking layer BM2 is disposed in the second type pixel, the second emission mode of the display device 10 may control the side visibility of light emitted from the second type pixel.

In the first emission mode, both the first pixel PX1 and the second pixel PX2 emit light and may be visually recognized from the front and the side. Accordingly, in the first pixel PX1, in order to ensure visibility from the side, the diameters of the pixel electrodes AE1, AE2, and AE3 and the holes OPT1, OPT2, and OPT3 may be larger than or equal to a certain level. On the other hand, in the second emission mode, only the second pixel PX2 may emit light, while the first pixel PX1 may not emit light, and the side visibility may be restricted. In the second emission mode, light of the second pixel PX2 may not be visually recognized at a side viewing angle except for a viewing angle close to the front. The diameter of the holes OPT4, OPT5, and OPT6 disposed in the second pixel PX2 may be little different from the diameter of the pixel electrodes AE1, AE2, and AE3, and the visibility may be restricted even at a small side viewing angle. In addition, the second light blocking layer BM2, which will be described later, may be provided in the second pixel PX2 to further restrict the side visibility.

In an embodiment, in the display device 10, the pixel electrodes AE1, AE2, and AE3 of the same type disposed in each of the first pixel PX1 and the second pixel PX2, e.g., the first pixel electrode AE1 of the first pixel PX1 and the first pixel electrode AE1 of the second pixel PX2, may have the same diameter, and the first hole OPT1 disposed in the first pixel PX1 may have a larger diameter than the fourth hole OPT4 disposed in the second pixel PX2. In an embodiment, the difference in diameter between the pixel electrodes AE1, AE2, and AE3 and the holes OPT4, OPT5, and OPT6 of the second pixel PX2 may be adjusted according to the patterning process performance of the first light blocking layer BM1, and the difference in diameter between the pixel electrodes AE1, AE2, and AE3 and the holes OPT1, OPT2, and OPT3 of the first pixel PX1 may be adjusted according to the optical distance from the pixel electrodes AE1, AE2, and AE3 in addition to the patterning process performance.

In an embodiment, the difference in diameter between the pixel electrodes AE1, AE2, and AE3 and the holes OPT4, OPT5, and OPT6 of the second pixel PX2 may be about 1.0 μm to about 1.5 μm, or about 1.2 μm, and a diameter difference DB1 between the pixel electrodes AE1, AE2, and AE3 and the holes OPT1, OPT2, and OPT3 of the first pixel PX1 may be about 4.5 μm to about 6.5 μm, or about 5 μm. The difference in diameter between the pixel electrodes AE1, AE2, and AE3 and the holes OPT1, OPT2, and OPT3 of the first pixel PX1 may be larger than the difference in diameter between the pixel electrodes AE1, AE2, and AE3 and the holes OPT4, OPT5, and OPT6 of the second pixel PX2. In another embodiment, the diameter difference DB1 between the holes OPT1, OPT2, and OPT3 of the first pixel PX1 and the opening of the pixel defining layer PDL may be larger than a diameter difference DB2 between the holes OPT4, OPT5, and OPT6 of the second pixel PX2 and the opening of the pixel defining layer PDL. The difference in diameter between the holes OPT1, OPT2, and OPT3 of the first pixel PX1 and the holes OPT4, OPT5, and OPT6 of the second pixel PX2 may be a value designed in consideration of the above-described optical distance, e.g., the distance between the pixel electrodes AE1, AE2, and AE3 and the top surface of the second encapsulation layer TFE2. However, the invention is not limited thereto, and the difference in diameter between the holes disposed in the first pixel PX1 and the second pixel PX2 may be designed and modified in various ways according to optical characteristic conditions that are necessary for the electronic device 1, or that may be required for the electronic device 1.

In an embodiment, the display device 10 may include the divided portions DBP1, DBP2, and DBP3 disposed around the holes OPT4, OPT5, and OPT6 in the second pixel PX2. The first divided portion DBP1 may be disposed to surround the fourth hole OPT4. The first light blocking layer BM1 may include a pattern portion located between the fourth hole OPT4 and the first divided portion DBP1. Although not shown in FIG. 11, as described above, the first light blocking layer BM1 may include the second divided portion DBP2 disposed to surround the fifth hole OPT5, and the third divided portion DBP3 disposed to surround the sixth hole OPT6.

Since the plurality of divided portions DBP1, DBP2, and DBP3 are disposed in the second pixel PX2, the diameters of the holes OPT4, OPT5, and OPT6 of the second pixel PX2 may be smaller than those of the holes OPT1, OPT2, OPT3 of the first pixel PX1, and the gap between the adjacent holes OPT4, OPT5, and OPT6 may be slightly reduced. For example, if the divided portions DBP1, DBP2, and DBP3 are not disposed, the distance between the adjacent holes OPT4, OPT5, and OPT6 of the second pixel PX2 may be larger than that between the adjacent holes OPT1, OPT2, and OPT3 of the first pixel PX1, and the thickness difference of the color filters CF1, CF2, and CF3 disposed thereon may be large. However, in the display device 10, the thicknesses of the color filters CF1, CF2, and CF3 disposed in the second pixel PX2 may be reduced by the divided portions DBP1, DBP2, and DBP3 disposed in the second pixel PX2. Accordingly, the thickness difference of the color filters CF1, CF2, and CF3 disposed in the first pixel PX1 and the second pixel PX2 may be reduced, and the transmittance difference in the different pixels PX1 and PX2 may also be reduced.

In an embodiment, the first light blocking layer BM1 may include a light absorbing material. For example, the first light blocking layer BM1 may include an inorganic black pigment or an organic black pigment. The inorganic black pigment may be carbon black, and the organic black pigment may include at least one of lactam black, perylene black, or aniline black, but they are not limited thereto. The first light blocking layer BM1 may prevent visible light infiltration and color mixture between the holes OPT1, OPT2, and OPT3, which leads to the improvement of color reproducibility of the display device 10. In an embodiment, the first light blocking layer BM1 may have a thickness of about 1 μm to about 3 μm, or approximately 1.5 μm.

In an embodiment, the color filters CF1, CF2, and CF3 of the color filter layer CFL may be disposed on the first light blocking layer BM1. The different color filters CF1, CF2, and CF3 may be disposed to correspond to the different pixel electrodes AE1, AE2, and AE3 and the holes OPT1, OPT2, and OPT3 of the first light blocking layer BM1, respectively. For example, the first color filter CF1 may be disposed to correspond to the first pixel electrode AE1, the second color filter CF2 may be disposed to correspond to the second pixel electrode AE2, and the third color filter CF3 may be disposed to correspond to the third pixel electrode AE3. In the first pixel PX1, the first color filter CF1 may be disposed in the first hole OPT1 of the first light blocking layer BM1, the second color filter CF2 may be disposed in the second hole OPT2 of the first light blocking layer BM1, and the third color filter CF3 may be disposed in the third hole OPT3 of the first light blocking layer BM1. In the second pixel PX2, the first color filter CF1 may be disposed in the fourth hole OPT4 of the first light blocking layer BM1, the second color filter CF2 may be disposed in the fifth hole OPT5 of the first light blocking layer BM1, and the third color filter CF3 may be disposed in the sixth hole OPT6 of the first light blocking layer BM1. Each of the color filters CF1, CF2, and CF3 may be disposed to have a larger area in a plan view than the hole OPT1, OPT2, OPT3 of the first light blocking layer BM1, and a part thereof may be disposed directly on the first light blocking layer BM1.

In an embodiment, the areas of the plurality of color filters CF1, CF2, and CF3 may vary depending on the sizes of the holes OPT1, OPT2, OPT3, OPT4, OPT5, and OPT6 of the first light blocking layer BM1. For example, the first color filter CF1 may have a larger area in a plan view than the second color filter CF2, but may have a smaller area in a plan view than the third color filter CF3. On the other hand, in an embodiment, the first color filter CF1 disposed in the first pixel PX1 may have the same area in a plan view as the first color filter CF1 disposed in the second pixel PX2. However, the invention is not limited thereto. In an embodiment, the first color filter CF1 disposed in the first pixel PX1 may have a larger area in a plan view than the first color filter CF1 disposed in the second pixel PX2.

In accordance with an embodiment, the thicknesses of the color filters CF1, CF2, and CF3 disposed in the first pixel PX1 may be different from those of the color filters CF1, CF2, and CF3 disposed in the second pixel PX2. The diameters of the holes OPT1, OPT2, and OPT3 of the first pixel PX1 may be larger than those of the holes OPT4, OPT5, and OPT6 of the second pixel PX2, and the color filters CF1, CF2, and CF3 covering them may have different thicknesses in the first pixel PX1 and the second pixel PX2. For example, in an embodiment, a thickness TH1 of the first color filter CF1 covering the first hole OPT1 of the first pixel PX1 may be smaller than a thickness TH2 of the first color filter CF1 covering the fourth hole OPT4 of the second pixel PX2. However, the first color filter CF1 of the second pixel PX2 may be disposed to cover both the fourth hole OPT4 and the first divided portion DBP1, and the thickness difference (TH2−TH1) with the first color filter CF1 of the first pixel PX1 may be reduced.

Although not shown in the drawing, the thickness of the second color filter CF2 covering the second hole OPT2 of the first pixel PX1 may be smaller than that of the second color filter CF2 covering the fifth hole OPT5 of the second pixel PX2. The thickness of the third color filter CF3 covering the third hole OPT3 of the first pixel PX1 may be smaller than that of the third color filter CF3 covering the sixth hole OPT6 of the second pixel PX2. However, the second color filter CF2 and the third color filter CF3 of the second pixel PX2 may be disposed to cover all the fifth hole OPT5 and the second divided portion DBP2, and the sixth hole OPT6 and the third divided portion DBP3, respectively, and the thickness difference with the color filters CF2 and CF3 of the first pixel PX1 may be reduced.

In an embodiment, the transmittance of light emitted from the first pixel PX1 and the transmittance of light emitted from the second pixel PX2 may be different due to the thickness difference of the color filters CF1, CF2, and CF3, but the transmittance difference and the thickness difference of the color filters CF1, CF2, and CF3 may be reduced by the divided portions DBP1, DBP2, and DBP3. Accordingly, the luminance difference between the first pixel PX1 and the second pixel PX2 in the first emission mode may be reduced.

In an embodiment, the passivation layers PSV1 and PSV2 may be disposed on the first light blocking layer BM1 and the color filter layer CFL. The passivation layers PSV1 and PSV2 may be disposed over the entire display area DA to flatten the top surface of the display panel 100. The passivation layers PSV1 and PSV2 may include a first passivation layer PSV1 disposed on the color filter layer CFL and the first light blocking layer BM1, and a second passivation layer PSV2 disposed on the first passivation layer PSV1. The passivation layers PSV1 and PSV2 may be formed of a plurality of layers and flatten the stepped portion caused by the color filter layer CFL and the first light blocking layer BM1.

However, the invention is not limited thereto. In an embodiment, the first passivation layer PSV1 may be patterned to partially expose the holes OPT4, OPT5, and OPT6 in the second pixel PX2. In this case, the light emission efficiency may be improved by adjusting the refractive index with the second passivation layer PSV2.

The passivation layers PSV1 and PSV2 may be a colorless light transmissive layer that does not have a color in a visible light band. For example, the passivation layers PSV1 and PSV2 may include a colorless light transmissive organic material such as an acrylic resin.

In an embodiment, the second light blocking layer BM2 may be disposed on the passivation layers PSV1 and PSV2. The second light blocking layer BM2 may not be disposed in the first type pixel (or the first pixel PX1), but may be disposed only in the second type pixel (or the second pixel PX2). The second light blocking layer BM2 may be disposed to correspond the periphery of the pixel electrodes AE1, AE2, and AE3 of the second type pixel, and may form transmission portions OPB1, OPB2, and OPB3 formed to overlap the pixel electrodes AE1, AE2, and AE3. For example, in an embodiment, the second light blocking layer BM2 may include a first transmission portion OPB1 overlapping the first pixel electrode AE1, a second transmission portion OPB2 overlapping the second pixel electrode AE2, and a third transmission portion OPB3 overlapping the third pixel electrode AE3. The transmission portions OPB1, OPB2, and OPB3 may overlap the holes OPT4, OPT5, and OPT6 of the first light blocking layer BM1, respectively.

In an embodiment, the diameter or area in a plan view of the transmission portions OPB1, OPB2, and OPB3 of the second light blocking layer BM2 may be larger than the diameter or area in a plan view of the holes OPT4, OPT5, and OPT6 of the first light blocking layer BM1, and the pixel electrodes AE1, AE2, and AE3. Light emitted from the light emitting element ED including the pixel electrodes AE1, AE2, and AE3 may be emitted through the holes OPT4, OPT5, and OPT6 of the first light blocking layer BM1 and the transmission portions OPB1, OPB2, and OPB3 of the second light blocking layer BM2. The light emitted from the second type pixel is finally emitted after passing through the transmission portions OPB1, OPB2, and OPB3, and a lot of light may be visually recognized at least when the display device 10 is viewed from the front.

However, when the display device 10 is viewed from the side, the light emitted from the second type pixel may be blocked by the second light blocking layer BM2 even if the light passes through the holes OPT4, OPT5, and OPT6 of the first light blocking layer BM1. In other words, the display device 10 may allow only the second pixel PX2 or the second type pixel in which the second light blocking layer BM2 is disposed to emit light in the second emission mode, thereby controlling visibility at a specific viewing angle and providing a privacy protection mode to the user.

In an embodiment, the second light blocking layer BM2 may include a light absorbing material. For example, the second light blocking layer BM2 may include an inorganic black pigment or an organic black pigment. The inorganic black pigment may be carbon black, and the organic black pigment may include at least one of lactam black, perylene black, or aniline black, but they are not limited thereto. In an embodiment, the second light blocking layer BM2 may have a thickness of about 1 μm to about 3 μm, or approximately 1.5 μm.

In an embodiment, the overcoat layer OC may be disposed on the second light blocking layer BM2 and the passivation layers PSV1 and PSV2. The overcoat layer OC may be disposed over the entire display area DA to flatten the top surface of the display panel 100. The overcoat layer OC may be a colorless light transmissive layer that does not have a color in a visible light band. For example, the overcoat layer OC may include a colorless light transmissive organic material such as an acrylic resin.

Hereinafter, various embodiments of the display device 10 will be described with reference to other drawings.

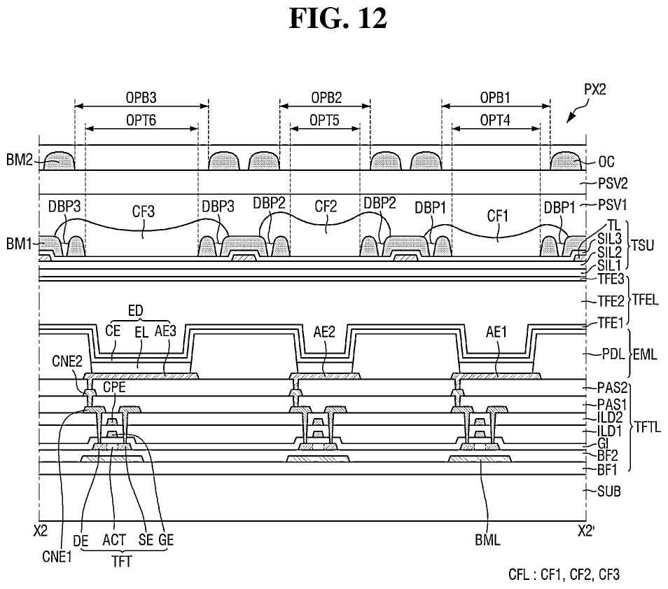

FIG. 12 is a diagram showing a cross section of a second pixel of a display device, according to another embodiment.

In an embodiment and referring to FIG. 12, in the display device 10, the color filters CF1, CF2, and CF3 disposed in the pixels PX1 and PX2 of the same type may have different thicknesses. For example, the first color filter CF1, the second color filter CF2, and the third color filter CF3 disposed in the second pixel PX2 may have different thicknesses. For example, the thickness of the second color filter CF2 may be larger than those of the first color filter CF1 and the third color filter CF3, and the thickness of the third color filter CF3 may be larger than that of the first color filter CF1.

Although not shown in the drawing, the color filters CF1, CF2, and CF3 of the first pixel PX1 may have the same thickness or different thicknesses. When the color filters CF1, CF2, and CF3 of the first pixel PX1 have different thicknesses, the color filters CF1, CF2, and CF3 disposed in the second pixel PX2 may also have different thicknesses. On the other hand, when the color filters CF1, CF2, and CF3 of the first pixel PX1 have the same thickness, a degree of reduction of the thicknesses of the color filters CF1, CF2, and CF3 by the diameter difference of the holes OPT4, OPT5, and OPT6, and the sizes of the divided portions DBP1, DBP2, and DBP3 may vary depending on materials forming the color filters CF1, CF2, and CF3. For example, even if the first color filter CF1 and the second color filter CF2 of the first pixel PX1 have the same thickness, the first color filter CF1 and the second color filter CF2 of the second pixel PX2 may have different thicknesses. Accordingly, in each of the first pixel PX1 and the second pixel PX2, the thickness difference between the first color filters CF1 may be different from the thickness difference between the second color filters CF2.

The thickness change rate may vary depending on the materials forming the color filters CF1, CF2, and CF3. For example, an appropriate thickness of the first color filter CF1 in which the transmittance is highest may be smaller than an appropriate thickness of the second color filter CF2 in which the transmittance is highest. Further, an appropriate thickness of the third color filter CF3 in which the transmittance is highest may be smaller than an appropriate thickness of the second color filter CF2 in which the transmittance is highest. Accordingly, the first color filter CF1 and the third color filter CF3 may have a thickness smaller than that of the second color filter CF2. The thicknesses of the color filters CF1, CF2, and CF3 may be variously changed in consideration of the change in the transmittance by the color filters CF1, CF2, and CF3 in the second pixel PX2.

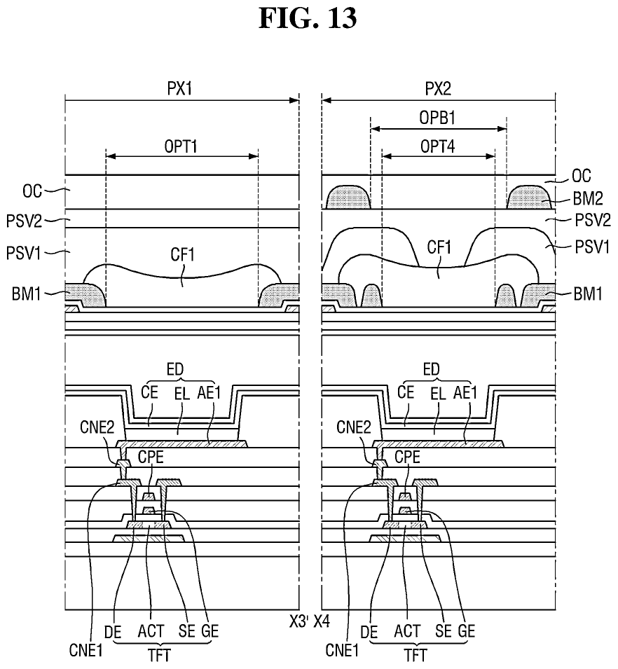

FIG. 13 is a diagram showing a cross section of a first pixel and a second pixel of a display device, according to another embodiment.

In an embodiment and referring to FIG. 13, in the display device 10, the first passivation layer PSV1 may be patterned in the second pixel PX2. The first passivation layer PSV1 may be disposed to completely cover the first light blocking layer BM1 and the color filters CF1, CF2, and CF3 in the first pixel PX1, and may be partially patterned in the second pixel PX2. For example, the first passivation layer PSV1 may be patterned to partially expose the plurality of color filters CF1, CF2, and CF3, and may be disposed to partially overlap the light blocking patterns of the first light blocking layer BM1.

In an embodiment, since the first passivation layer PSV1 is patterned in the second pixel PX2, the patterned first passivation layer PSV1 may form an inclined side surface on the color filters CF1, CF2, and CF3. The inclined side surface of the first passivation layer PSV1 may be in contact with the second passivation layer PSV2 to form an interface, and lights incident on the inclined side surface may be emitted in an upward direction. In an embodiment, the first passivation layer PSV1 may include a material having a refractive index lower than that of the second passivation layer PSV2, and lights incident on the side surface of the first passivation layer PSV1 among lights emitted through the color filters CF1, CF2, and CF3 may be emitted in an upward direction.

The color filters CF1, CF2, and CF3 may be in contact with each of the first passivation layer PSV1 and the second passivation layer PSV2, and lights emitted from the light emitting element ED of the second pixel PX2 may be incident on the first passivation layer PSV1 or the second passivation layer PSV2 through the color filters CF1, CF2, and CF3. Some of the lights incident on the second passivation layer PSV2 may be refracted at the side surface of the first passivation layer PSV1 and emitted in an upward direction. Accordingly, even if the transmittance is slightly low because the thicknesses of the color filters CF1, CF2, and CF3 disposed in the second pixel PX2 are larger than the thicknesses of the color filters CF1, CF2, and CF3 disposed in the first pixel PX1, the efficiency difference caused by the transmittance difference may be minimized by improving the light emission efficiency in an upward direction.

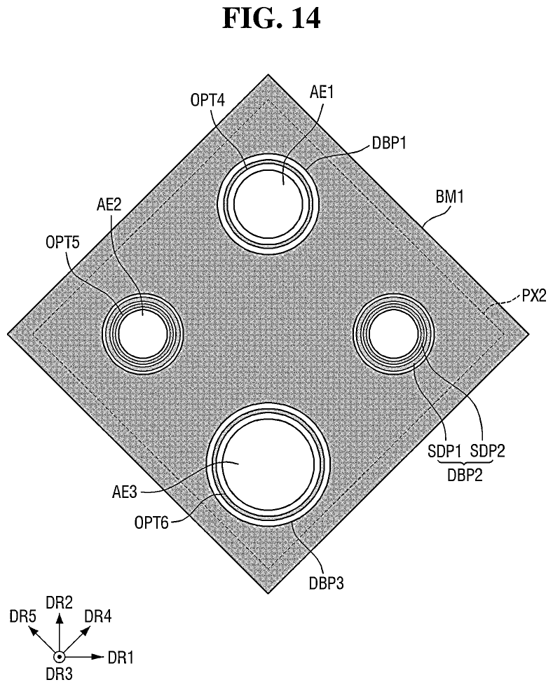

FIGS. 14 to 16 are plan views illustrating the disposition of a pixel electrode and a first light blocking layer in a display area of a display device, according to another embodiment.

In an embodiment and referring to FIG. 14, in the display device 10, the structure of the divided portions DBP1, DBP2, and DBP3 disposed in the second pixel PX2 may vary depending on the diameter difference of the holes OPT4, OPT5, and OPT6. In an embodiment, among the divided portions DBP1, DBP2, and DBP3 of the first light blocking layer BM1, the second divided portion DBP2 may include a first sub-divided portion SDP1 and a second sub-divided portion SDP2. The first sub-divided portion SDP1 may surround the fifth hole OPT5, and the second sub-divided portion SDP2 may surround the first sub-divided portion SDP1. The second divided portion DBP2 may have a multi-divided structure, unlike the first divided portion DBP1 and the third divided portion DBP3.

The second divided portion DBP2 that is a divided portion formed to correspond to the fifth hole OPT5 having a relatively small diameter may have a diameter smaller than those of other adjacent divided portions (e.g., the first divided portion DBP1 and the third divided portion DBP3). Since the diameter of the fifth hole OPT5 is small, a space where a plurality of divided portions can be disposed may exist therearound. The second divided portion DBP2 may have a multi-divided structure within a range that does not interfere with other adjacent divided portions, and may include the plurality of sub-divided portions SDP1 and SDP2 to further reduce the thicknesses of the color filters CF1, CF2, and CF3.

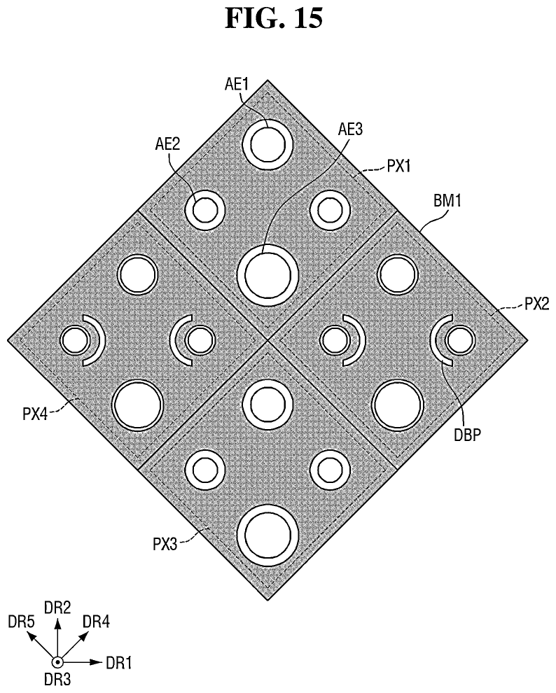

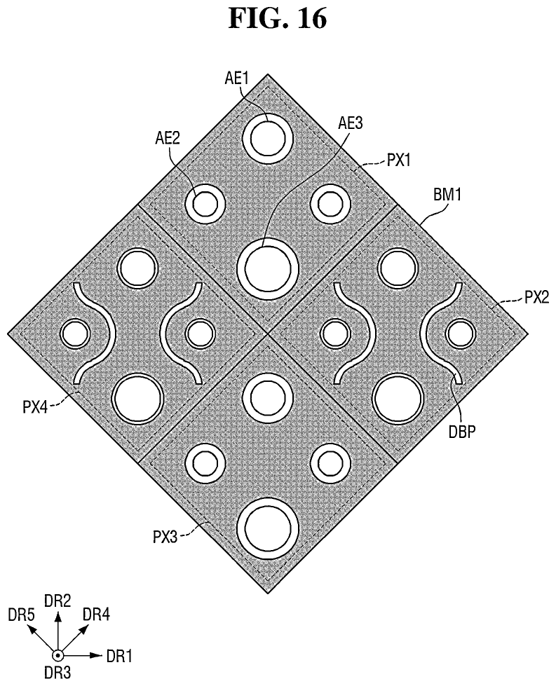

In an embodiment and referring to FIGS. 15 and 16, in the display device 10, the divided portion DBP may not necessarily have a shape surrounding the holes OPT4, OPT5, and OPT6. In an embodiment, the shape of the divided portion DBP may be variously modified as long as the divided portion DBP is disposed around the plurality of holes OPT4, OPT5, and OPT6 located in the second pixel PX2 to overlap the color filters CF1, CF2, and CF3.

For example, in the display device 10 of FIG. 15, the divided portions DBP may be disposed only around the fifth hole OPT5, or the second pixel electrode AE2 of the second pixel PX2. The divided portions DBP may be spaced apart from the fifth hole OPT5, have a predetermined width, and have a curved shape along a part of the outer side of the fifth hole OPT5. The divided portions DBP may have an arch shape corresponding to a circular hole.

In the display device 10 of FIG. 16, the divided portions DBP may be disposed between the fourth hole OPT4 and the fifth hole OPT5, and between the sixth hole OPT6 and the fifth hole OPT5. The divided portions DBP may have a curved shape along the outer sides of the plurality of holes OPT4, OPT5, and OPT6, and may be disposed such that light blocking portions of the first light blocking layer BM1 located between the fourth hole OPT4 and the sixth hole OPT6 are not continuous.

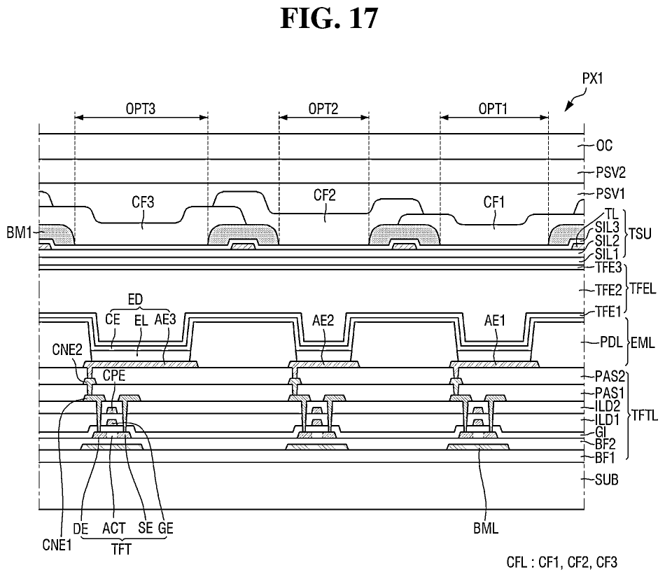

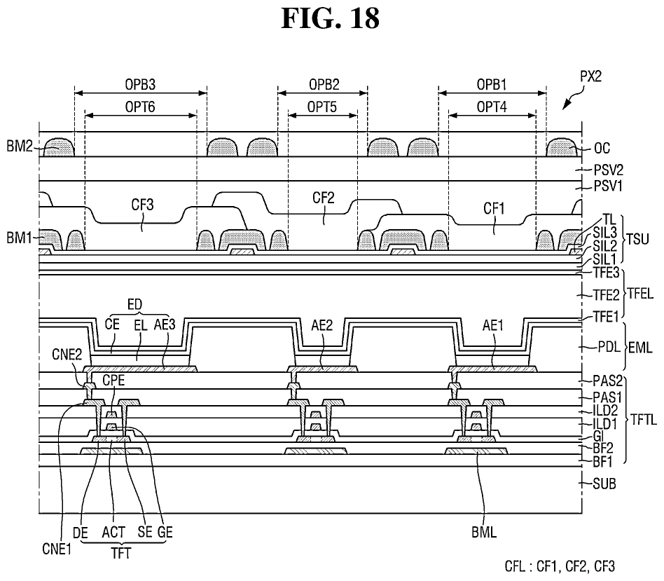

FIGS. 17 and 18 are cross-sectional views of a display device, according to another embodiment. FIG. 17 shows the cross section of the first pixel PX1, and FIG. 18 shows the cross section of the second pixel PX2.

In an embodiment and referring to FIGS. 17 and 18, in the display device 10, the color filters CF1, CF2, and CF3 may be disposed to partially overlap. The plurality of color filters CF1, CF2, and CF3 may overlap different color filters that are disposed adjacent to each other on the first light blocking layer BM1. For example, the second color filter CF2 may overlap each of the first color filter CF1 and the third color filter CF3 that is disposed adjacent to each other on the first light blocking layer BM1. Although not shown in the drawing, the first color filter CF1 may overlap the third color filter CF3 on the first light blocking layer BM1, and in various embodiments, all the first color filter CF1, the second color filter CF2, and the third color filter CF3 may overlap.

Also, in the second pixel PX2, the plurality of color filters CF1, CF2, and CF3 may overlap each other. The color filters CF1, CF2, and CF3 may be disposed to cover different holes OPT4, OPT5, and OPT6, and they may also cover the divided portions DBP1, DBP2, and DBP3 of the first light blocking layer BM1, respectively. The color filters CF1, CF2, and CF3 of the second pixel PX2 overlap each other on the first light blocking layer BM1 and thus may have thicker thicknesses. However, the thicknesses are slightly reduced by the divided portions, so that the thickness difference with the color filters CF1, CF2, and CF3 of the first pixel PX1 may be reduced.

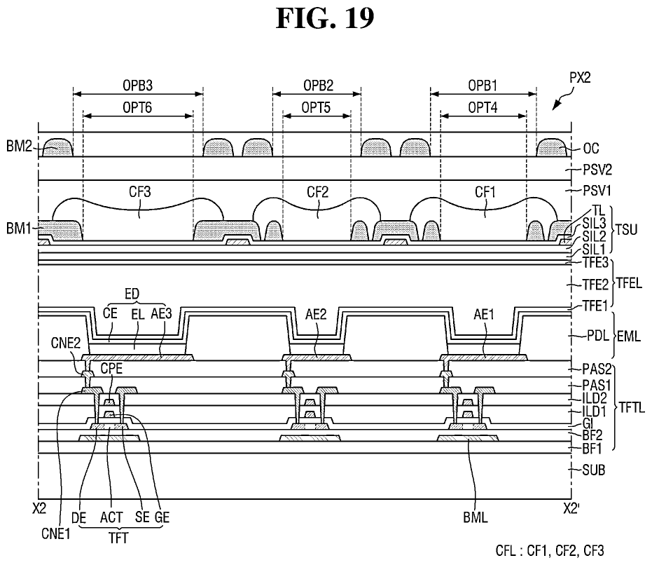

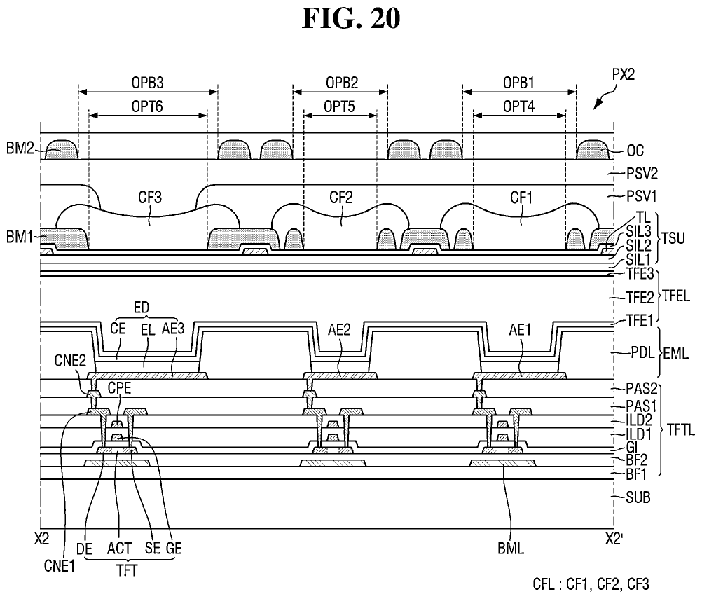

FIGS. 19 and 20 are cross-sectional views of a display device, according to still another embodiment. FIGS. 19 and 20 each show a cross section of the second pixel PX2.

In an embodiment and referring to FIG. 19, in the display device 10, in the first light blocking layer BM1, divided portions may be formed at different holes of the second pixel PX2, for example, the fourth hole OPT4 and the fifth hole OPT5, to correspond thereto, but a divided portion may not be formed at the sixth hole OPT6. For example, the divided portion may not be formed at the sixth hole OPT6 overlapping the third pixel electrode AE3 of the second pixel PX2. Since the sixth hole OPT6 of the first light blocking layer BM1 has a diameter larger than those of the fourth hole OPT4 and the fifth hole OPT5, the thickness of the third color filter CF3 may not be significantly different from the thicknesses of the other color filters CF1 and CF2 even if the divided portion is not formed. Accordingly, in the first light blocking layer BM1, the divided portions may be formed only at the fourth hole OPT4 and the fifth hole OPT5 of the second pixel PX2 to correspond thereto, and may not be formed at the sixth hole OPT6.

In an embodiment and referring to FIG. 20, in the display device 10, the first passivation layer PSV1 may be partially patterned only on the sixth hole OPT6 of the second pixel PX2. In the display device 10, the first passivation layer PSV1 may form an inclined side surface only on the sixth hole OPT6.

In concluding the detailed description, those skilled in the art will appreciate that many variations and modifications can be made to the invention without substantially departing from the scope and principles of the invention. Therefore, the disclosed embodiments of the invention are used in a generic and descriptive sense only and not for purposes of limitation. Each component specifically shown in the embodiments of the invention can be implemented by modification, and such modifications and differences related to application should be construed as being included in the scope of the invention. Moreover, the embodiments or parts of the embodiments may be combined in whole or in part without departing from the scope of the invention.

What is claimed is:

1. A display device comprising:
a display area in which a plurality of first pixels and second pixels comprising a plurality of pixel electrodes spaced apart from each other are disposed;
a first light blocking layer disposed in the display area and comprising a plurality of holes disposed to overlap the plurality of pixel electrodes;
a plurality of color filters disposed on the first light blocking layer and disposed to correspond to the plurality of holes; and
a second light blocking layer disposed on the plurality of color filters to correspond to the plurality of pixel electrodes of the plurality of second pixels,
wherein the first light blocking layer further comprises a plurality of divided portions disposed around the plurality of holes of the plurality of second pixels and penetrating the first light blocking layer, and
the plurality of color filters disposed in the plurality of second pixels are disposed to cover the hole of the first light blocking layer and the divided portion disposed to correspond to the hole.

2. The display device of claim 1, wherein the first light blocking layer comprises:
a first hole overlapping a first pixel electrode of the plurality of first pixels;
a second hole overlapping a second pixel electrode of the plurality of first pixels;
a third hole overlapping a first pixel electrode of the plurality of second pixels; and
a fourth hole overlapping a second pixel electrode of the plurality of second pixels,
wherein a diameter of the first hole is larger than a diameter of the third hole.

3. The display device of claim 2, wherein a distance between the first hole and the second hole in the first pixel is smaller than a distance between the third hole and the fourth hole in the second pixel.

4. The display device of claim 2, wherein
the plurality of divided portions comprise a first divided portion surrounding the third hole, and a second divided portion surrounding the fourth hole, and
a diameter of a region surrounded by the first divided portion is larger than a diameter of a region surrounded by the second divided portion.

5. The display device of claim 4, wherein the second divided portion comprises a first sub-divided portion surrounding the fourth hole, and a second sub-divided portion surrounding the first sub-divided portion.

6. The display device of claim 1, wherein the plurality of divided portions are spaced apart from an outer side of the plurality of holes located in the plurality of second pixels, and have a curved shape along the outer side.

7. The display device of claim 1, wherein the plurality of divided portions are disposed between the plurality of holes located in the plurality of second pixels.

8. The display device of claim 1, wherein a pixel of the plurality of first pixels and the plurality of second pixels comprise a first pixel electrode, and a second pixel electrode having a diameter smaller than that of the first pixel electrode, and
wherein the second light blocking layer comprises:
a first light blocking pattern surrounding an outer side of the first pixel electrode and forming a first transmission portion overlapping the first pixel electrode; and
a second light blocking pattern surrounding an outer side of the second pixel electrode and forming a second transmission portion overlapping the second pixel electrode.

9. The display device of claim 8, wherein a diameter of the first transmission portion is smaller than a diameter of the second transmission portion.

10. The display device of claim 8, wherein a separation distance between the outer side of the first pixel electrode and an inner side of the first light blocking pattern is different from a separation distance between the outer side of the second pixel electrode and an inner side of the second light blocking pattern.

11. A display device comprising:
a substrate on which a first pixel and a second pixel comprising a plurality of pixel electrodes are disposed;
an encapsulation layer disposed on the plurality of pixel electrodes;
a first light blocking layer disposed on the encapsulation layer and comprising a plurality of holes each disposed to correspond to one of the plurality of pixel electrodes;
a plurality of color filters disposed on the first light blocking layer and disposed to correspond to the plurality of holes;
a passivation layer disposed on the plurality of color filters and the first light blocking layer;
a second light blocking layer disposed on the passivation layer in the second pixel and comprising a plurality of light blocking patterns forming a plurality of transmission portions each overlapping the plurality of pixel electrodes of the second pixel; and
an overcoat layer disposed on the second light blocking layer, wherein
the plurality of pixel electrodes comprise a first pixel electrode and a second pixel electrode having a diameter smaller than that of the first pixel electrode, which are disposed in each of the first pixel and the second pixel,
the first light blocking layer is disposed around the plurality of holes disposed in the second pixel and comprises a plurality of divided portions penetrating the first light blocking layer, and
among the plurality of color filters, the plurality of color filters disposed in the second pixel are disposed to cover the plurality of divided portion.

12. The display device of claim 11, wherein the passivation layer comprises a first passivation layer disposed on the first light blocking layer and the plurality of color filters, and a second passivation layer disposed on the first passivation layer.

13. The display device of claim 12, wherein the first passivation layer is disposed to cover the plurality of color filters and the first light blocking layer in the first pixel, and is patterned to partially expose the plurality of color filters in the second pixel.

14. The display device of claim 12, wherein the first passivation layer has a refractive index lower than that of the second passivation layer.

15. The display device of claim 12, wherein the first passivation layer is in contact with the second passivation layer on the plurality of color filters disposed in the second pixel and forms an inclined side surface.

16. The display device of claim 11, wherein the first light blocking layer comprises:
a first hole overlapping the first pixel electrode of the first pixel;
a second hole overlapping the second pixel electrode of the first pixel;
a third hole overlapping the first pixel electrode of the second pixel; and
a fourth hole overlapping the second pixel electrode of the second pixel,
wherein a diameter of the first hole is larger than a diameter of the third hole, and
wherein a thickness of the plurality of color filters disposed on the first hole among the plurality of color filters is smaller than a thickness of the plurality of color filter disposed on the third hole.

17. The display device of claim 16, wherein among the plurality of color filters, a thickness of the plurality of color filters disposed on the second hole is smaller than a thickness of the plurality of color filters disposed on the fourth hole.

18. The display device of claim 16, wherein a difference in thickness between the plurality of color filters disposed on the first hole and the plurality of color filters disposed on the third hole is different from a difference in thickness between the plurality of color filters disposed on the second hole and the plurality of color filters disposed on the fourth hole.

19. The display device of claim 16, wherein the plurality of color filters overlap each other on the first light blocking layer.

20. The display device of claim 19, wherein the plurality of color filters disposed on the second hole is disposed on the plurality of color filters disposed on the first hole on the first light blocking layer.
